(19) United States
(12) Patent Application Publication
(10) Pub. No.: US 2013/0030731 A1
(43) Pub. Date: Jan. 31, 2013

(54) ALTERNATING-CURRENT ELECTRIC QUANTITY MEASURING APPARATUS AND ALTERNATING-CURRENT ELECTRIC QUANTITY MEASURING METHOD

(71) Applicant: Kempei Seki, Tokyo (JP)

(72) Inventor: Kempei Seki, Tokyo (JP)

(73) Assignee: Mitsbbishi Electric Corporation, Chiyoda-ku (JP)

(21) Appl. No.: 13/639,269

(22) PCT Filed: Jun. 2, 2010
(86) PCT No.: PCT/JP2010/059392

§ 371 Date: Oct. 4, 2012

(51) Int. Cl. G01R 25/00; G06F 19/00; G01R 21/06; G01R 19/00

(52) U.S. Cl. 702/60; 702/64

(57) ABSTRACT

According to a present alternating-current electric quantity measuring apparatus, a voltage amplitude calculated by a square integral operation of at least three continuous voltage instantaneous values sampled at a sampling frequency twice or higher than a frequency of an alternating-current voltage to be measured is normalized. A voltage chord length calculated by the square integral operation of three voltage chord length instantaneous values representing an end-to-end distance between two adjacent voltage instantaneous values in at least four continuous voltage instantaneous values including the three voltage instantaneous values, which are sampled at the sampling frequency and used in calculating the normalized voltage amplitude, is normalized. A rotation phase angle in one period time of sampling is calculated using the normalized voltage amplitude and the normalized voltage chord length. A frequency of the alternating-current voltage is calculated using the calculated rotation phase angle.

### FIELD

The present invention relates to an alternating-current electric quantity measuring apparatus and an alternating-current electric quantity measuring method.

### BACKGROUND

In recent years, as a current flow in a power system becomes complicated, supply of electric power with high reliability and quality is demanded. In particular, necessity of improvement of performance of an alternating-current electric quantity measuring apparatus that measures electric quantities (alternating-current electric quantities) of a power system is becoming higher.

In the past, as the alternating-current electric quantity measuring apparatus of this type, there are apparatuses disclosed in Patent Literatures 1 and 2 listed below. In Patent Literature 1 (a protection control measuring system) and Patent Literature 2 (a wide-area protection control measuring system), a method of calculating a frequency of a real system using a change component (a differential component) of a phase angle as a change from a rated frequency (50 hertz or 60 hertz) is disclosed.

In these literatures, as a calculation equation for calculating the frequency of the real system, the following equations are disclosed. However, these calculation equations are calculation equations presented by Non Patent Literature 1 listed below as well.

2πΔf=dφ/dt

f(Hz)=60+Δf

Patent Literature 3 listed below is the invention of the earlier filed application of the inventor of this application. Contents of the invention are explained below.

### CITATION LIST

### Patent Literature

Patent Literature 1: Japanese Patent Application Laid-open No. 2009-65766
Patent Literature 2: Japanese Patent Application Laid-open No. 2009-71637
Patent Literature 3: Japanese Patent Application Laid-open No. 2007-325429

### Non Patent Literature

Non Patent Literature 1: “IEEE Standard for Power Synchrophasors for Power Systems” page 30, IEEE Std C37. 118-2005.

### SUMMARY

### Technical Problem

As explained above, the method disclosed in Patent Literatures 1 and 2 and Non Patent Literature 1 is a method of calculating a change component of a phase angle using a differential calculation. However, a change in a frequency instantaneous value of the real system is frequent and complicated and the differential calculation is extremely unstable. Therefore, there is a problem in that sufficient calculation accuracy cannot be obtained concerning, for example, frequency measurement.

In the method, the frequency of the real system is calculated using the rated frequency (50 hertz or 60 hertz) as an initial value. Therefore, there is a problem in that, when a measurement target is operating at a frequency deviating from the system rated frequency during the start of the calculation, a measurement error occurs and. When a degree of the deviation from the system rated frequency is large, the measurement error is extremely large.

The present invention has been devised in view of the above and it is an object of the present invention to provide an alternating-current electric quantity measuring apparatus and an alternating-current electric quantity measuring method that enable highly-accurate measurement of alternating-current electric quantities even if a measuring target is operating at a frequency deviating from a system rated frequency.

### Solution to Problem

In order to solve above-mentioned problems and achieve the object, there is provided an alternating-current electric quantity measuring apparatus according to the present invention including: a normalized-voltage-amplitude calculating unit configured to calculate a normalized voltage amplitude obtained by normalizing a voltage amplitude calculated by a square integral operation of voltage instantaneous value data of continuous at least three points obtained by sampling an alternating-current voltage to be measured at a sampling frequency twice or more as high as a frequency of the alternating-current voltage; a normalized-voltage-chord-length calculating unit configured to calculate a normalized voltage chord length obtained by normalizing a voltage chord length calculated by the square integral operation of voltage chord length instantaneous value data of three points representing an end-to-end distance between voltage instantaneous value data of adjacent two points in voltage instantaneous value data of continuous at least four points including the voltage instantaneous value data of the three points, which are sampled at the sampling frequency and used in calculating the normalized voltage amplitude; and a frequency calculating unit configured to calculate a rotation phase angle in one period time of sampling using the normalized voltage amplitude and the normalized voltage chord length and calculate a frequency of the alternating-current voltage using the calculated rotation phase angle.

### Advantageous Effects of Invention

The alternating-current electric quantity measuring apparatus according to the present invention has an advantageous effect that it is possible to perform highly-accurate measurement of alternating-current electric quantities even if a measuring target is operating at a frequency deviating from a system rated frequency.

### BRIEF DESCRIPTION OF DRAWINGS

FIG. 1 is a diagram of a normalized voltage amplitude symmetric group on a complex plane.

FIG. 2 is a diagram of a normalized voltage chord length symmetric group on the complex plane.

FIG. 3 is a diagram for explaining a relation between a normalized voltage amplitude and a normalized voltage chord length on the complex plane.

FIG. 4 is a diagram of six voltage rotation vectors arranged on the complex plane.

FIG. 5 is a diagram of eight voltage rotation vectors arranged on the complex plane.

FIG. 6 is a diagram of an example of a voltage vector, a current vector, and a power vector arranged on the complex plane.

FIG. 7 is a diagram of a normalized power symmetric group on the complex plane.

FIG. 8 is a diagram of a functional configuration of an alternating-current electric quantity measuring apparatus 1 according to a present embodiment.

FIG. 9 is a flowchart for explaining a flow of processing in the alternating-current electric quantity measuring apparatus.

FIG. 10 is a graph of a waveform of a voltage instantaneous value during execution of a first simulation and a normalized voltage amplitude and a normalized chord length calculated based on the voltage instantaneous value.

FIG. 11 is a graph of a rotation phase angle calculated in the first simulation.

FIG. 12 is a graph of a real frequency calculated in the first simulation.

FIG. 13 is a graph of a real voltage amplitude calculated in the first simulation.

FIG. 14 is a graph of a normalized voltage amplitude, a normalized chord length, and a real voltage amplitude calculated in a second simulation.

FIG. 15 is a graph of a change in a rotation phase angle calculated in the second simulation.

FIG. 16 is a graph of a frequency gain characteristic during execution of the second simulation.

FIG. 17 is a graph of a normalized active power and a real active power calculated in a third simulation.

FIG. 18 is a graph of a normalized reactive power and a real reactive power calculated in the third simulation.

FIG. 19 is a graph of a normalized voltage-to-current phase angle and a real reactive power calculated in the third simulation.

FIG. 20 is a graph of a rotation phase angle calculated in a fourth simulation.

FIG. 21 is a graph of a real frequency calculated in the fourth simulation.

FIG. 22 is a graph of a normalized voltage amplitude and a real voltage amplitude calculated in the fourth simulation.

FIG. 23 is a graph of a normalized current amplitude and a real current amplitude calculated in the fourth simulation.

FIG. 24 is a graph of a normalized active power and a real active power calculated in the fourth simulation.

FIG. 25 is a graph of a normalized reactive power and a real reactive power calculated in the fourth simulation.

FIG. 26 is a graph of a normalized voltage-to-current phase angle and a real voltage-to-current phase angle calculated in the fourth simulation.

FIG. 27 is a graph for explaining a relation between a first proportionality coefficient (a normalized voltage amplitude and chord length proportionality coefficient) and a rotation phase angle.

FIG. 28 is a graph for explaining a relation between the first proportionality coefficient (the normalized voltage amplitude and chord length proportionality coefficient) and a second proportionality coefficient (a sampling frequency proportionality coefficient).

FIG. 29 is a flowchart for explaining a procedure for calculating a real frequency using a sampling frequency identifying method.

### DESCRIPTION OF EMBODIMENTS

An alternating-current electric quantity measuring apparatus according to an embodiment of the present invention is explained below with reference to the accompanying drawings. The present invention is not limited by the embodiment explained below.

### Embodiment

In explaining an alternating-current electric quantity measuring apparatus and an alternating-current electric quantity measuring method according to a present embodiment, first, a concept (an algorithm) of the alternating-current electric quantity measuring method forming the gist of this embodiment is explained. Thereafter, a configuration and an operation of the alternating-current electric quantity measuring apparatus according to this embodiment are explained. In the following explanation, among alphabet small letter notations, those with parentheses (e.g., “v(t)”) represent vectors and those without parentheses (e.g., “v₂”) represent instantaneous values. Alphabet capital letter notations (e.g., “V_{f}”) represent effective values or amplitude values.

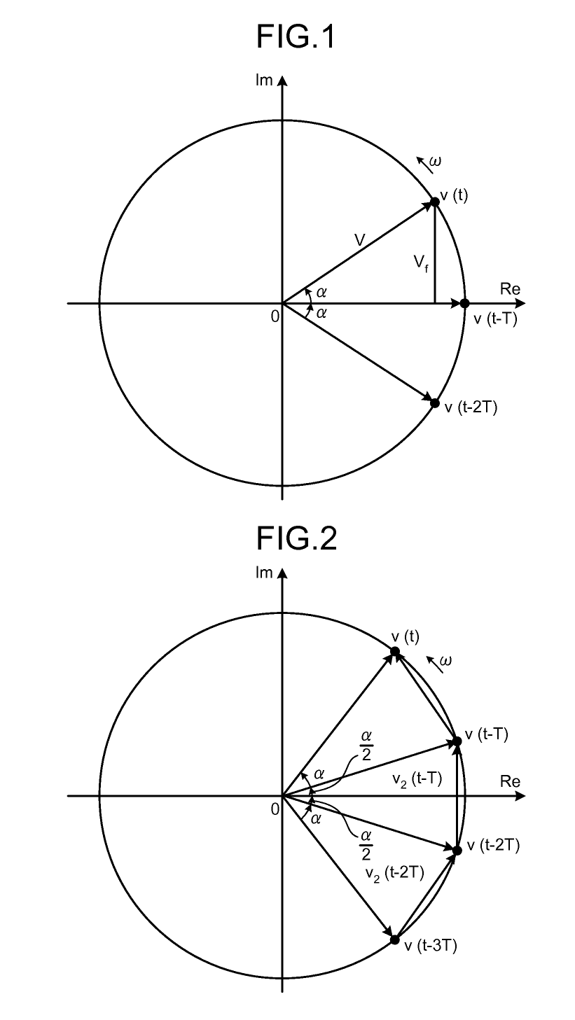

FIG. 1 is a diagram of a normalized voltage amplitude symmetric group on a complex plane. In FIG. 1, on the complex plane, a voltage rotation vector v(t) at the present point, a voltage rotation vector v(t−T) at a point earlier than the present point by one period of sampling T (time equivalent to one interval of a sampling frequency), and a voltage rotation vector v(t−2T) at a point earlier than the present point by two periods of sampling (2T) are shown.

These three voltage rotation vectors are examined. First, the three voltage rotation vectors are rotation vectors that rotate counterclockwise on the complex plane at the same rotation velocity. The voltage rotation vectors are represented as indicated by the following equation using the sampling period T:

$$\begin{matrix} v ( t ) = V {e}^{j ( ω t + α )} \\ v ( t - T ) = V {e}^{j ω t} \\ v ( t - 2 T ) = V {e}^{j ( ω t - α )}\end{matrix} \} \qquad ( 1 )$$

In equation (1), V represents a real voltage amplitude. ω represents a rotation angular velocity, which is represented by the following equation:

ω=2πf (2)

In equation (2), f represents a real frequency. The one period of sampling T in equation (1) is represented by the following equation:

$$T = \frac{1}{{f}_{s}} \qquad ( 3 )$$

In equation (3), fₛ represents a sampling frequency. α shown in equation (1) represents a rotation phase angle, which means an angle α voltage vector rotates on the complex plane in the time of the one period of sampling T.

Referring to FIG. 1, it is seen that, in the three voltage vectors, voltage vectors (v(t), v(t−2T)) on both sides have symmetry with respect to the voltage vector (v(t−T)) in the middle. The three voltage rotation vectors form one voltage rotation vector group that rotates counterclockwise on the complex plane at the same rotation velocity. One normalized voltage amplitude value explained below is defined. According to these characteristics, the three voltage rotation vectors are defined as a normalized voltage amplitude symmetric group.

Subsequently, a calculation equation for a normalized voltage amplitude, which is an amplitude value of the normalized voltage amplitude symmetric group, is explained. First, the calculation equation for the normalized voltage amplitude is defined as indicated by the following equation:

V_{f}=\sqrt{v²₂−v₁v₃} (4)

In equation (4), v₂ represents a real part of a second voltage rotation vector in the normalized voltage amplitude symmetric group, v₁ represents a real part of a first voltage rotation vector in the normalized voltage amplitude symmetric group, and v₃ represents a real part of a third voltage rotation vector in the normalized voltage amplitude symmetric group. The real parts v₁, v₂, and v₃ are respectively calculated using the following equation:

$$\begin{matrix}\begin{matrix}{v}_{1} = Re [ v ( t ) ] = V cos ( ω t + α ) \\ {v}_{2} = Re [ v ( t - T ) ] = V cos ( ω t ) \end{matrix} \\ {v}_{3} = Re [ v ( t - 2 T ) ] = V cos ( ω t - α )\end{matrix} \} \qquad ( 5 )$$

In equation (5), a sign “Re” indicates a real part of a complex vector component. If equation (5) is substituted in the right side of equation (4), equation (4) is expanded as indicated by the following equation:

$$\begin{matrix}\begin{matrix}\begin{matrix}{V}_{f} = \sqrt{{v}_{2}^{2} - {v}_{1} {v}_{3}} \\ = V \sqrt{[ {cos}^{2} ( ω t ) - cos ( ω t + α ) cos ( ω t - α ) ]}\end{matrix} \\ = V \sqrt{\frac{1}{2} [ cos ( 2 ω t ) + 1 - cos ( 2 ω t ) - cos ( 2 α ) ]}\end{matrix} \\ = V \sqrt{\frac{1}{2} [ 1 - cos ( 2 α ) ]} \\ = V sin α \end{matrix} \} \qquad ( 6 )$$

In other words, the normalized voltage amplitude V_{f} is represented by the following equation:

V_{f}=V sin α (7)

As represented by equation (7), the normalized voltage amplitude V_{f} is represented by a product of the real voltage amplitude V and a sine function of the rotation phase angle α. The frequency f and the rotation phase angle α correspond in a one-to-one relation. Therefore, the normalized voltage amplitude V_{f} corresponding to the fixed frequency f is a fixed value. A relation between the normalized voltage amplitude V_{f} and the frequency f is converted into a relation between the normalized voltage amplitude V_{f} and the rotation phase angle α. Therefore, if the rotation phase angle α is given, the real voltage amplitude V is known.

If equation (7) is further examined, characteristics explained below are made clear (however, a fluctuation range of the real frequency is set to “0 to fₛ/2”).

(a) When the rotation phase angle α is 90 degrees, the normalized voltage amplitude V_{f} and the real voltage amplitude V are equal. The real frequency is ¼ of the sampling frequency.
(b) When the rotation phase angle α is smaller than 90 degrees, if the sampling frequency fₛ increases (the one period time of sampling T decreases), the rotation phase angle α also decreases and the normalized voltage amplitude V_{f} decreases. Conversely, if the sampling frequency fₛ decreases (the one period time of sampling T increases), the rotation phase angle α also increases and the normalized voltage amplitude V_{f} increases.
(c) On the other hand, when the rotation phase angle α is larger than 90 degrees, if the sampling frequency fₛ increases (the one period time of sampling T decreases), the rotation phase angle α also decreases and the normalized voltage amplitude V_{f} increases. Conversely, if the sampling frequency fₛ decreases (the one period time of sampling T increases), the rotation phase angle α also increases and the normalized voltage amplitude V_{f} decreases.
(d) A limit of the rotation phase angle α is 180 degrees. A real frequency at the limit is ½ of the sampling frequency. In other words, this characteristic is a characteristic itself of a sampling theorem in the communication field.

Subsequently, a normalized voltage chord length is explained with reference to FIG. 2. FIG. 2 is a diagram of a normalized voltage chord length symmetric group on the complex plane. In FIG. 2, on the complex plane, a voltage rotation vector v(t) at the present point, a voltage rotation vector v(t−T) at a point earlier than the present point by one period of sampling T, a voltage rotation vector v (t−2T) at a point earlier than the present point by two periods of sampling (2T), and a voltage rotation vector v(t−3T) at a point earlier than the present point by three periods of sampling (3T) are shown. Further, a voltage differential vector v₂(t) between v(t) and v(t−T), a voltage differential vector v₂(t−T) between v(t−T) and v(t−2T), and a voltage differential vector v₂(t−2T) between v(t−2T) and v(t−3T) are shown.

These three voltage differential vectors are examined. First, like the three voltage rotation vectors shown in FIG. 1, the three voltage differential vectors are represented as indicated by the following equation using the real voltage amplitude V, the rotation velocity ω, and the rotation phase angle α:

$$\begin{matrix}\begin{matrix}{v}_{2} ( t ) = v ( t ) - v ( t - T ) = V {e}^{j ( ω t + \frac{3 α}{2} )} - V {e}^{j ( ω t + \frac{α}{2} )} \\ {v}_{2} ( t - T ) = v ( t - T ) - v ( t - 2 T ) = V {e}^{j ( ω t + \frac{α}{2} )} - V {e}^{j ( ω t - \frac{α}{2} )}\end{matrix} \\ {v}_{2} ( t - 2 T ) = v ( t - 2 T ) - v ( t - 3 T ) = V {e}^{j ( ω t - \frac{α}{2} )} - V {e}^{j ( ω t - \frac{3 α}{2} )}\end{matrix} \} \qquad ( 8 )$$

Referring to FIG. 2, it is seen that, in the three voltage differential vectors, voltage differential vectors (v₂(t), v₂(t−2T)) with advanced phases have symmetry with respect to the voltage vector (v₂(t−T)) in the middle. The three voltage differential vectors form one voltage chord length vector group that rotates counterclockwise on the complex plane at the same rotation velocity. Normalized one value (voltage chord length) explained below is defined. According to these characteristics, the three voltage differential vectors are defined as a normalized voltage amplitude and chord length symmetric group.

Subsequently, a calculation equation for a normalized voltage chord length, which is an amplitude value of the normalized voltage chord length symmetric group, is explained. First, the calculation equation for the normalized voltage chord length is defined as indicated by the following equation:

V_{f 2}=\sqrt{v²₂₂−v₂₁v₂₃} (9)

In equation (9), v₂₂ represents a real part of a second voltage differential vector (v₂(t−T)) in the normalized voltage chord length symmetric group, v₂₁ represents a real part of a first voltage differential vector (v₂(t)) in the normalized voltage chord length symmetric group, and v₂₃ represents a real part of a third voltage differential vector (v₂(t−2T)) in the normalized voltage amplitude symmetric group. The real parts are respectively calculated using the following equation:

$$\begin{matrix}\begin{matrix}{v}_{21} = Re [ {v}_{2} ( t ) ] = V [ cos ( ω t + \frac{3 α}{2} ) - cos ( ω t + \frac{α}{2} ) ] \\ {v}_{22} = Re [ {v}_{2} ( t - T ) ] = V [ cos ( ω t + \frac{α}{2} ) - cos ( ω t - \frac{α}{2} ) ] \end{matrix} \\ {v}_{23} = Re [ {v}_{2} ( t - 2 T ) ] = V [ cos ( ω t - \frac{α}{2} ) - cos ( ω t - \frac{3 α}{2} ) ]\end{matrix} \} \qquad ( 10 )$$

If equation (10) is substituted in an expression in a square root sign on the right side of equation (9), equation (9) is expanded as indicated by the following equation:

$$\begin{matrix}\begin{matrix}\begin{matrix}\begin{matrix}\begin{matrix}{v}_{22}^{2} - {v}_{21} {v}_{23} = {V}^{2} \{ \begin{matrix}\begin{matrix}{[ cos ( ω t + \frac{α}{2} ) - cos ( ω t - \frac{α}{2} ) ]}^{2} - \\ [ cos ( ω t + \frac{3 α}{2} ) - cos ( ω t + \frac{α}{2} ) ]\end{matrix} \\ [ cos ( ω t - \frac{α}{2} ) - cos ( ω t - \frac{3 α}{2} ) ]\end{matrix} \} \\ = {V}^{2} [ \begin{matrix}{cos}^{2} ( ω t + \frac{α}{2} ) + {cos}^{2} ( ω t - \frac{α}{2} ) - \\ 2 cos ( ω t + \frac{α}{2} ) cos ( ω t - \frac{α}{2} ) - \\ cos ( ω t + \frac{3 α}{2} ) cos ( ω t - \frac{α}{2} ) + \\ cos ( ω t + \frac{3 α}{2} ) cos ( ω t - \frac{3 α}{2} ) + \\ cos ( ω t + \frac{α}{2} ) cos ( ω t - \frac{α}{2} ) - \\ cos ( ω t + \frac{α}{2} ) cos ( ω t - \frac{3 α}{2} )\end{matrix} ] \\ = \frac{{V}^{2}}{2} \{ \begin{matrix}\begin{matrix}\begin{matrix}cos ( 2 ω t + α ) + cos ( 2 ω t - α ) + 2 - \\ 2 [ cos ( 2 ω t ) + cos α ] - cos ( 2 ω t + α ) -\end{matrix} \\ cos ( 2 ω t + α ) - cos ( 2 α ) + cos ( 2 ω t ) + cos ( 3 α ) +\end{matrix} \\ cos ( 2 ω t ) + cos ( α ) - cos ( 2 ω t - α ) - cos ( 2 α )\end{matrix} \}\end{matrix} \\ = \frac{{V}^{2}}{2} [ cos ( 3 α ) - 2 cos ( 2 α ) - cos α + 2 ]\end{matrix} \\ = 2 {V}^{2} ( {cos}^{3} α - cos α - {cos}^{2} α + 1 )\end{matrix} \\ = 2 {V}^{2} ( - cos α {sin}^{2} α + {sin}^{2} α )\end{matrix} \\ = 4 {V}^{2} {sin}^{2} {αsin}^{2} \frac{α}{2}\end{matrix} \} \qquad ( 11 )$$

Therefore, according to equations (9) and (11), a normalized voltage chord length V_{f2} is represented by the following equation:

$${V}_{f 2} = 2 V sin αsin \frac{α}{2} \qquad ( 12 )$$

As represented by equation (12), the normalized voltage chord length V_{f2} is represented by a product of the real voltage amplitude V, a sine function of the rotation phase angle α, a sine function of ½ of the rotation phase angle α. Like the normalized voltage amplitude V₂, because the frequency f and the rotation phase angle α correspond in a one-to-one relation, the normalized voltage chord length V_{f2} corresponding to a fixed frequency is a fixed value. A relation between the normalized voltage chord length V_{f2} and the frequency f is converted into a relation between the normalized voltage amplitude V_{f2} and the rotation phase angle α.

A relational expression of the following equation is obtained according to equations (7) and (12):

$$\frac{{V}_{f}}{{V}_{f 2}} = \frac{V sin α}{2 V sin α sin \frac{α}{2}} = \frac{1}{2 sin \frac{α}{2}} \qquad ( 13 )$$

Therefore, the rotation phase angle α is represented as indicated by the following equation from equation (13):

$$α = 2 {sin}^{- 1} ( \frac{{V}_{f 2}}{2 {V}_{f}} ) \qquad ( 14 )$$

If equation (14) is used, the rotation phase angle α can be calculated. Specifically, it is sufficient to calculate a normalized voltage amplitude using the normalized voltage amplitude symmetric group, calculate a normalized voltage chord length using the normalized voltage chord length symmetric group, and calculate a rotation phase angle in one period time of a sampling frequency using the normalized voltage amplitude and the normalized voltage chord length. Equation (14) means that a calculation result of the rotation phase angle does not depend on the rotation vector voltage amplitude V and depends on only a frequency. This fact is embodied by the conception of the inventor of this application that vector calculation is performed using the normalized voltage amplitude symmetric group and the normalized voltage chord length symmetric group.

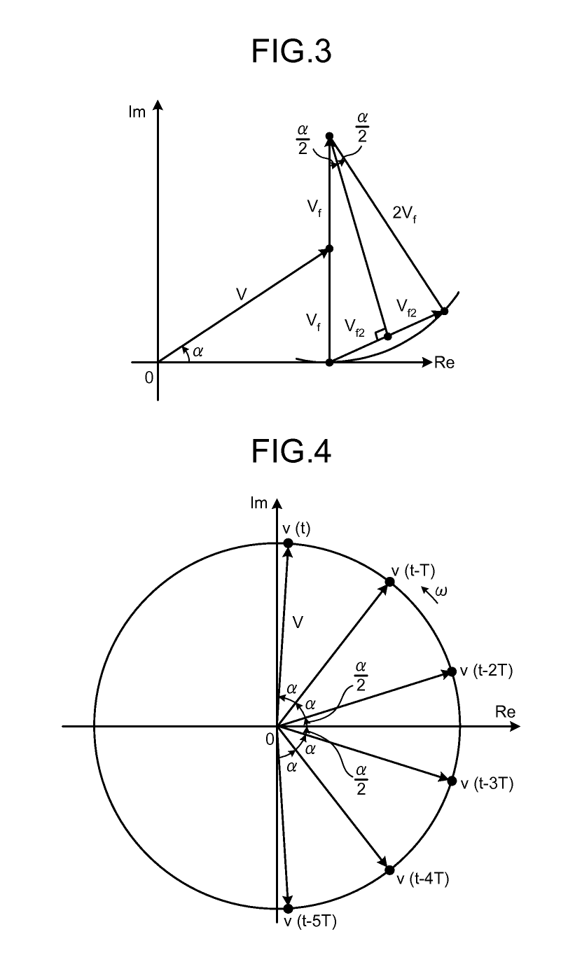

FIG. 3 is a diagram for explaining a relation between the normalized voltage amplitude and the normalized voltage chord length on the complex plane. A triangle formed by the normalized voltage amplitude and the normalized voltage chord length (hereinafter referred to as “normalized amplitude and chord length rotation triangle”) indicated by a thick solid line is shown.

The normalized amplitude and chord length rotation triangle is formed in an isosceles triangular shape. The oblique sides have length of 2V_{f} and the base has length of 2V_{f2}. Like the normalized voltage amplitude symmetric group and the normalized voltage chord length symmetric group, the normalized amplitude and chord length rotation triangle rotates counterclockwise on the complex plane.

Although not explained above, the rotation phase angle α can be represented by the following equation:

α=ωT=2πfT (15)

Therefore, a real frequency can be calculated as indicated by the following equation using the rotation phase angle α.

$$f = \frac{α}{2 π T} \qquad ( 16 )$$

Subsequently, rotational invariance of the normalized voltage amplitude symmetric group and the normalized voltage chord length symmetric group is explained.

In the “normalized voltage amplitude symmetric group on the complex plane” shown in FIG. 1 and the “normalized voltage chord length symmetric group on the complex plane” shown in FIG. 2, the arrangement of the rotation vectors is arrangement at arbitrary time t. On the other hand, time t does not appear in equation (7) calculated with reference to FIG. 1 and equation (12) calculated with reference to FIG. 2. This means that, no matter how the normalized voltage amplitude symmetric group and the normalized voltage chord length symmetric group are arranged, equations (7), (12), (14), and (16) concerning the normalized voltage amplitude, the normalized voltage chord length, the rotation phase angle, and the frequency hold. Therefore, such a characteristic is referred to as rotational invariance of the normalized voltage amplitude symmetric group and the normalized voltage chord length symmetric group.

In the equation expansion explained above, the real part (a cosine function) of the voltage rotation vector is used as the voltage instantaneous value. However, an imaginary part (a sine function) of the voltage rotation vector can also be used as the voltage instantaneous value. Even if such equation expansion is performed, the rotational invariance of the normalized voltage amplitude symmetric group and the normalized voltage chord length symmetric group holds. To prove this, equation expansion is explained below.

First, imaginary parts of three voltage rotation vectors are designated as indicated by the following equation as time series voltage instantaneous value data in equation (4).

$$\begin{matrix}\begin{matrix}{v}_{1} = Im [ v ( t ) ] = V sin ( ω t + α ) \\ {v}_{2} = Im [ v ( t - T ) ] = V sin ( ω t ) \end{matrix} \\ {v}_{3} = Im [ v ( t - 2 T ) ] = V sin ( ω t - α )\end{matrix} \} \qquad ( 17 )$$

In equation (17), a sign “Im” indicates an imaginary part of a complex vector component. If equation (17) is substituted in the right side of equation (4), equation (4) is expanded as indicated by the following equation:

$$\begin{matrix}\begin{matrix}\begin{matrix}{V}_{f} = \sqrt{{v}_{2}^{2} - {v}_{1} {v}_{3}} \\ = V \sqrt{[ {sin}^{2} ( ω t ) - sin ( ω t + α ) sin ( ω t - α ) ]} \end{matrix} \\ = V \sqrt{\frac{1}{2} [ cos ( 2 ω t ) + 1 - cos ( 2 ω t ) - cos ( 2 α ) ]}\end{matrix} \\ = V \sqrt{\frac{1}{2} [ 1 - cos ( 2 α ) ]} \\ = V sin α \end{matrix} \} \qquad ( 18 )$$

As it is evident when equation (18) is compared with equation (7), it is seen that both the equations coincide with each other.

The same equation expansion is performed concerning the normalized voltage chord length. First, imaginary parts of three voltage differential vectors are designated as time series voltage instantaneous value data in equation (10) as indicated by the following equation:

$$\begin{matrix}\begin{matrix}{v}_{21} = Im [ {v}_{2} ( t ) ] = V [ sin ( ω t + \frac{3 α}{2} ) - sin ( ω t + \frac{α}{2} ) ] \\ {v}_{22} = Im [ {v}_{2} ( t - T ) ] = V [ sin ( ω t + \frac{α}{2} ) - sin ( ω t - \frac{α}{2} ) ]\end{matrix} \\ {v}_{23} = Im [ {v}_{2} ( t - 2 T ) ] = V [ sin ( ω t - \frac{α}{2} ) - sin ( ω t - \frac{3 α}{2} ) ]\end{matrix} \} \qquad ( 19 )$$

If equation (19) is substituted in an expression in a square root sine on the right side of equation (9), equation (9) is expanded as indicated by the following equation:

$$\begin{matrix}\begin{matrix}\begin{matrix}\begin{matrix}\begin{matrix}{v}_{22}^{2} - {v}_{21} {v}_{23} = {V}^{2} \{ \begin{matrix}\begin{matrix}{[ sin ( ω t + \frac{α}{2} ) - sin ( ω t - \frac{α}{2} ) ]}^{2} - \\ [ sin ( ω t + \frac{3 α}{2} ) - sin ( ω t + \frac{α}{2} ) ]\end{matrix} \\ [ sin ( ω t - \frac{α}{2} ) - sin ( ω t - \frac{3 α}{2} ) ]\end{matrix} \} \\ = {V}^{2} [ \begin{matrix}{sin}^{2} ( ω t + \frac{α}{2} ) + {sin}^{2} ( ω t - \frac{α}{2} ) - \\ 2 sin ( ω t + \frac{α}{2} ) sin ( ω t - \frac{α}{2} ) - \\ sin ( ω t + \frac{3 α}{2} ) sin ( ω t - \frac{α}{2} ) + \\ sin ( ω t + \frac{3 α}{2} ) sin ( ω t - \frac{3 α}{2} ) + \\ sin ( ω t + \frac{α}{2} ) sin ( ω t - \frac{α}{2} ) - \\ sin ( ω t + \frac{α}{2} ) sin ( ω t - \frac{3 α}{2} )\end{matrix} ] \\ = \frac{{V}^{2}}{2} \{ \begin{matrix}\begin{matrix}\begin{matrix}2 - cos ( 2 ω t + α ) - cos ( 2 ω t - α ) - \\ 2 [ cos α - cos ( 2 ω t ) ] - cos ( 2 α ) -\end{matrix} \\ cos ( 2 ω t + α ) + cos ( 3 α ) - cos ( 2 ω t ) + cos α -\end{matrix} \\ cos ( 2 ω t ) - cos ( 2 α ) - cos ( 2 ω t - α )\end{matrix} \}\end{matrix} \\ = \frac{{V}^{2}}{2} [ cos ( 3 α ) - 2 cos ( 2 α ) - cos α + 2 ]\end{matrix} \\ = 2 {V}^{2} ( {cos}^{3} α - cos α - {cos}^{2} α + 1 )\end{matrix} \\ = 2 {V}^{2} ( - cos α {sin}^{2} α + {sin}^{2} α )\end{matrix} \\ = 4 {V}^{2} {sin}^{2} {αsin}^{2} \frac{α}{2}\end{matrix} \} \qquad ( 20 )$$

If equation (20) is substituted in Equation (9), equation (12) is obtained.

In this way, it can be considered that the normalized voltage amplitude symmetric group and the normalized voltage chord length symmetric group have the characteristic of rotational invariance.

The calculation equations for the normalized voltage amplitude and the normalized voltage chord length according to the normalized voltage amplitude symmetric group by the three voltage rotation vector (the three sampling points) and the normalized voltage chord length symmetric group by the four voltage rotation vector (the four sampling points) are explained above. However, sampling points are not limited to these sampling points in calculating the normalized voltage amplitude and the normalized voltage chord length. It is also possible to increase the number of sampling points. Therefore, calculation equations formed when the number of sampling points is increased is presented below.

First, a calculation equation for a normalized voltage amplitude according a normalized voltage amplitude symmetric group having n voltage rotation vectors (the number of sampling points is n) is as shown below.

$${V}_{f} = \sqrt{\frac{1}{n - 2} ( {\sum }_{k = 2}^{n - 1} ( {v}_{k}^{2} - {v}_{k - 1} {v}_{k + 1} ) )} = V sin α , n \geq 3 \qquad ( 21 )$$

Time series data of voltage instantaneous values can be represented by the following equation:

vₖ=Re{v[t−(k−1)T]}, k=1, 2, . . . , n (22)

Time series data of voltage rotation vectors can be represented by the following equation:

v[t−(k−1)T]=Ve^{j[ωt-(k-1)α]}, k=1, 2, . . . , n (23)

Similarly, a calculation equation for a normalized voltage chord length according to a normalized voltage chord length symmetric group having n+1 voltage rotation vectors (the number of sampling points is n+1) can be generalized as shown below.

$${V}_{f 2} = \sqrt{\frac{1}{n - 2} ( {\sum }_{k = 2}^{n - 1} ( {v}_{2 k}^{2} - {v}_{2 ( k - 1 )} {v}_{2 ( k + 1 )} ) )} = 2 V sin α sin \frac{α}{2} , \\ n \geq 3 \qquad ( 24 )$$

Time series data of differential voltage instantaneous values can be represented by the following equation:

v₂ₖ=Re{v(t−kT)−v[t−(k−1)T]}, k=1, 2, . . . , n (25)

Time series data of voltage differential vectors can be represented by the following equation:

V₂[t−(k−1)T]=Ve^{j(ωt-(kα)}−Ve^{j[ωt-(k-1)α]}, k=1, 2, . . . , n (26)

Subsequently, several variations concerning the calculation equations for the normalized voltage amplitude and the normalized voltage chord length are explained with reference to FIG. 4. FIG. 4 is a diagram of six voltage rotation vectors arranged on the complex plane. According to the six voltage rotation vectors, four normalized voltage amplitude symmetric group can be defined as follows.

(a) Normalized voltage amplitude symmetric group 1 v(t), v(t−T), v(t−2T)
(b) Normalized voltage amplitude symmetric group 2 v(t−T), v(t−2T), v(t−3T)
(c) Normalized voltage amplitude symmetric group 3 v(t−2T), v(t−3T), v(t−4T)
(d) Normalized voltage amplitude symmetric group 4 v(t−3T), v(t−4T), v(t−5T)

When all the four normalized voltage amplitude symmetric group according to (a) to (d) are used, a normalized voltage amplitude can be calculated using the following equation:

$${V}_{f} = \sqrt{\frac{1}{4} ( {v}_{2}^{2} - {v}_{1} {v}_{3} + {v}_{3}^{2} - {v}_{2} {v}_{4} + {v}_{4}^{2} - {v}_{3} {v}_{5} + {v}_{5}^{2} - {v}_{4} {v}_{6} )} \qquad ( 27 )$$

In equation (27), time series data of voltage rotation vectors are as shown below.

$$\begin{matrix}\begin{matrix}\begin{matrix}\begin{matrix}\begin{matrix}v ( t ) = V {e}^{j ( ω t + \frac{5 α}{2} )} \\ v ( t - T ) = V {e}^{j ( ω t + \frac{3 α}{2} )}\end{matrix} \\ v ( t - 2 T ) = V {e}^{j ( ω t + \frac{α}{2} )}\end{matrix} \\ v ( t - 3 T ) = V {e}^{j ( ω t - \frac{α}{2} )}\end{matrix} \\ v ( t - 4 T ) = V {e}^{j ( ω t - \frac{3 α}{2} )}\end{matrix} \\ v ( t - 5 T ) = V {e}^{j ( ω t - \frac{5 α}{2} )}\end{matrix} \} \qquad ( 28 )$$

In equation (27), time series data of voltage instantaneous values is as shown below.

$$\begin{matrix}\begin{matrix}\begin{matrix}\begin{matrix}\begin{matrix}{v}_{1} = Re [ v ( t ) ] = V cos ( ω t + \frac{5 α}{2} ) \\ {v}_{2} = Re [ v ( t - T ) ] = V cos ( ω t + \frac{3 α}{2} )\end{matrix} \\ {v}_{3} = Re [ v ( t - 2 T ) ] = V cos ( ω t + \frac{α}{2} )\end{matrix} \\ {v}_{4} = Re [ v ( t - 3 T ) ] = V cos ( ω t - \frac{α}{2} )\end{matrix} \\ {v}_{5} = Re [ v ( t - 4 T ) ] = V cos ( ω t - \frac{3 α}{2} )\end{matrix} \\ {v}_{6} = Re [ v ( t - 5 T ) ] = V cos ( ω t - \frac{5 α}{2} )\end{matrix} \} \qquad ( 29 )$$

If equation (29) is substituted in an expression in a square root sign on the right side of equation (27), equation (27) is expanded as indicated by the following equation:

$$\frac{1}{4} [ ( {v}_{2}^{2} - {v}_{1} {v}_{3} ) + ( {v}_{3}^{2} - {v}_{2} {v}_{4} ) + ( {v}_{4}^{2} - {v}_{3} {v}_{5} ) + ( {v}_{5}^{2} - {v}_{4} {v}_{6} ) ] = \frac{{v}^{2}}{4} [ \begin{matrix}{cos}^{2} ( ω t + \frac{3 α}{2} ) - \\ cos ( ω t + \frac{5 α}{2} ) cos ( ω t + \frac{α}{2} ) + {cos}^{2} ( ω t + \frac{α}{2} ) - \\ cos ( ω t + \frac{3 α}{2} ) cos ( ω t - \frac{α}{2} ) + {cos}^{2} ( ω t - \frac{α}{2} ) - \\ cos ( ω t + \frac{α}{2} ) cos ( ω t - \frac{3 α}{2} ) + {cos}^{2} ( ω t - \frac{3 α}{2} ) - \\ cos ( ω t - \frac{α}{2} ) cos ( ω t - \frac{5 α}{2} )\end{matrix} ] = \frac{V}{2} ( 1 - cos 2 α ) = {V}^{2} {sin}^{2} α \qquad ( 30 )$$

Therefore, according to equations (27) and (30), the normalized voltage amplitude V_{f} is represented by the following equation. A same result as equation (7) is obtained.

v_{f}=\sqrt{¼(v₂²−v₁v₃+v₃²v₂v₄+v₄²−v₃v₅+v₅²−v₄v₆)}=V sin α (31)

Equation (27) is a calculation equation for a normalized voltage amplitude in which all the four normalized voltage amplitude symmetric groups according to (a) to (d) are used. However, equation (27) can be a calculation equation in which a part of the normalized voltage amplitude symmetric groups are used. For example, when two normalized voltage amplitude symmetric groups according to (a) and (d) are used, a calculation equation can be defined as indicated by the following equation:

V_{f}=\sqrt{½(v₂²−v₁v₃+v₅²−v₄v₆)} (32)

If the voltage instantaneous values of equation (29) are substituted in an expression of a square root sign on the right side of equation (32), equation (32) is expanded as indicated by the following equation:

$$\begin{matrix}\begin{matrix}\frac{1}{2} [ ( {v}_{2}^{2} - {v}_{1} {v}_{3} ) + ( {v}_{5}^{2} - {v}_{4} {v}_{6} ) ] \\ = \frac{{V}^{2}}{2} [ \begin{matrix}{cos}^{2} ( ω t + \frac{3 α}{2} ) - cos ( ω t + \frac{5 α}{2} ) cos ( ω t + \frac{α}{2} ) + \\ {cos}^{2} ( ω t - \frac{3 α}{2} ) - cos ( ω t - \frac{α}{2} ) cos ( ω t - \frac{5 α}{2} )\end{matrix} ]\end{matrix} \\ = \frac{{V}^{2}}{2} ( 1 - cos 2 α ) = {V}^{2} {sin}^{2} α\end{matrix} \} \qquad ( 33 )$$

Therefore, according to equations (32) and (33), the normalized voltage amplitude V_{f} is represented by the following equation. A same result as equations (7) and (31) is obtained.

V_{f}=\sqrt{½(v₂²+v₅²−v₁v₃−v₄v₆)}=V sin α (34)

Among the calculation equations (7), (31), and (33), effects for a calculation time increase in the order of (31), (33), and (7) and, effects for a calculation accuracy increase in the order of (7), (33), and (31). Therefore, it is desirable to determine, taking into account the calculation time and the calculation accuracy, which calculation equation is selected.

Prior to the invention of this application, the inventor of this application filed an application concerning measurement of alternating-current electric quantities (Patent Literature 3 cited as the related art document: hereinafter referred to as “invention of the earlier filed application”). In the invention of the earlier filed application, a calculation equation for a normalized voltage amplitude is disclosed. This calculation equation is explained.

In the invention of the earlier filed application, the calculation equation for the normalized voltage amplitude is disclosed as indicated by the following equation:

$${V}_{f} = \sqrt{\frac{1}{2 N} \{ {\sum }_{k = N}^{3 N - 1} {v}_{re}^{2} ( t - kT ) - {\sum }_{k = 0}^{2 N - 1} {v}_{re} ( t - kT ) \cdot {v}_{re} [ t - ( 2 N + k ) T ] \}} \qquad ( 35 )$$

In equation (35), N represents a positive integer called sampling division number. The sampling division number is a setting value (a set point) for changing a rotation phase angle (dividing the rotation phase angle by an integer). For example, if the sampling division number is increased, the rotation phase angle decreases and the calculation accuracy increases (however, the calculation time increases).

Time series data of voltage rotation vectors is as indicated by the following equation:

v[t−(k−1)T]=Ve^{j[ωt-(k-1)α]}, k=1, 2, . . . , 4N (36)

Time series data of voltage instantaneous values is a real part of a rotation vector and is as indicated by the following equation:

vᵣₑ[t−(k−1)T]=V cos [ωt−(k−1)α], k=1, 2, . . . , 4N (37)

If equation (37) is substituted in the right side of equation (35), equation (35) is simplified as indicated by the following equation:

$${V}_{f} = \sqrt{\frac{1}{2 N} \{ {\sum }_{k = N}^{3 N - 1} {v}_{re}^{2} ( t - kT ) - {\sum }_{k = 0}^{2 N - 1} {v}_{re} ( t - kT ) \cdot {v}_{re} [ t - ( 2 N + k ) T ] \}} = V sin ( N α ) \qquad ( 38 )$$

Similarly, in the invention of the earlier filed application, a calculation equation for a normalized voltage chord length is as indicated by the following equation:

$${V}_{f 2} = \sqrt{\frac{1}{2 N} \{ {{\sum }_{k = N}}^{3 N - 1} {v}_{2 re}^{2} ( t - kT ) - {\sum }_{k = 0}^{2 N - 1} {v}_{2 re} ( t - kT ) \cdot {v}_{2 re} [ t - ( 2 N + k ) T ] \}} \qquad ( 39 )$$

Time series data of voltage differential rotation vectors and differential voltage instantaneous values are as indicated by the following equations:

v₂[t−(k−1)T]=Ve^{j[ωt-(k-1)α]}−Ve^{j[ωt-(k-2)α]}, k=1, 2, . . . , 4N (40)

v₂ᵣₑ[t−(k−1)T]=V cos [ωt−(k−1)α]−V cos [ωt−(k−2)α], k=1, 2, . . . , 4N (41)

If equation (41) is substituted in the right side of equation (39), equation (39) is simplified as indicated by the following equation:

$$\begin{matrix}{V}_{f 2} = \sqrt{\frac{1}{2} \{ \begin{matrix}{\sum }_{k = N}^{3 N - 1} {v}_{2 re}^{2} ( t - kT ) - {\sum }_{k = 0}^{2 N - 1} {v}_{2 re} ( t - kT ) \cdot \\ {v}_{2 re} [ t - ( 2 N + k ) T ]\end{matrix} \}} \\ = 2 V sin ( N α ) sin \frac{α}{2}\end{matrix} \qquad ( 42 )$$

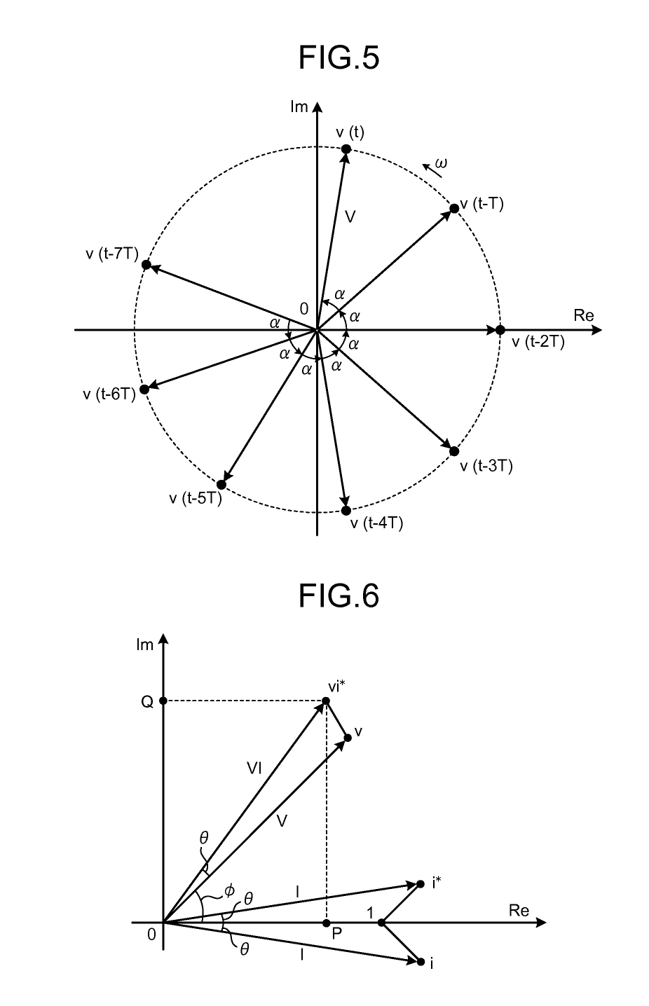

Subsequently, a calculation example employing the calculation equations of the invention of the earlier filed application is explained using voltage rotation vectors shown in FIG. 5. FIG. 5 is a diagram of eight voltage rotation vectors arranged on the complex plane.

In the case of the invention of the earlier filed application, a method of calculating four voltage rotation vectors as one unit (i.e., the sampling division number N=1) is adopted. Therefore, in the case of the eight voltage rotation vectors, N=2. The calculation equation for the normalized voltage amplitude is represented by the following equation:

$${V}_{f} = \sqrt{\frac{1}{4} \{ {\sum }_{k = 2}^{5} {v}_{re}^{2} ( t - kT ) - {\sum }_{k = 0}^{3} {v}_{re} ( t - kT ) \cdot {v}_{re} [ t - ( 4 + k ) T ] \}} \qquad ( 43 )$$

In the case of FIG. 5, the time series data of the voltage instantaneous values can be represented by the following equation:

$$\begin{matrix}{v}_{re} ( t ) = V cos ( ω t + 2 α ) \\ {v}_{re} ( t - T ) = V cos ( ω t + α ) \\ {v}_{re} ( t - 2 T ) = V cos ( ω t ) \\ {v}_{re} ( t - 3 T ) = V cos ( ω t - α ) \\ {v}_{re} ( t - 4 T ) = V cos ( ω t - 2 α ) \\ {v}_{re} ( t - 5 T ) = V cos ( ω t - 3 α ) \\ {v}_{re} ( t - 6 T ) = V cos ( ω t - 4 α ) \\ {v}_{re} ( t - 7 T ) = V cos ( ω t - 5 α )\end{matrix} \} \qquad ( 44 )$$

If equation (44) is substituted in an expression of a square root sign on the right side of equation (43), equation (43) is expanded as indicated by the following equation:

$$\frac{1}{4} \{ {\sum }_{k = 2}^{5} {v}_{re}^{2} ( t - kT ) - {\sum }_{k = 0}^{3} {v}_{re} ( t - kT ) \cdot {v}_{re} [ t - ( 4 + k ) T ] \} = \frac{1}{4} [ \begin{matrix}\begin{matrix}{v}_{re}^{2} ( t - 2 T ) - {v}_{re} ( t ) \cdot {v}_{re} ( t - 4 T ) + {v}_{re}^{2} ( t - 3 T ) - \\ {v}_{re} ( t - T ) \cdot {v}_{re} ( t - 5 T ) + {v}_{re}^{2} ( t - 4 T ) - {v}_{re} ( t - 2 T ) \cdot \end{matrix} \\ {v}_{re} ( t - 6 T ) + {v}_{re}^{2} ( t - 5 T ) - {v}_{re} ( t - 3 T ) \cdot {v}_{re} ( t - 7 T )\end{matrix} ] = \frac{{V}^{2}}{4} [ \begin{matrix}\begin{matrix}{cos}^{2} ( ω t ) - \\ cos ( ω t + 2 α ) cos ( ω t - 2 α ) + {cos}^{2} ( ω t - α ) - \\ cos ( ω t + α ) cos ( ω t - 3 α ) + {cos}^{2} ( ω t - 2 α ) -\end{matrix} \\ cos ( ω t ) cos ( ω t - 4 α ) + {cos}^{2} ( ω t - 3 α ) - \\ cos ( ω t - α ) cos ( ω t - 5 α )\end{matrix} ] = \frac{{V}^{2}}{2} [ 1 - cos ( 4 α ) ] = {V}^{2} {sin}^{2} ( 2 α ) \qquad ( 45 )$$

Therefore, according to equations (43) and (45), a result indicated by the following equation is obtained.

$${V}_{f} = \sqrt{\frac{1}{4} \{ {\sum }_{k = 2}^{5} {v}_{re}^{2} ( t - kT ) - {\sum }_{k = 0}^{3} {v}_{re} ( t - kT ) \cdot {v}_{re} [ t - ( 4 + k ) T ] \}} = V sin ( 2 α ) \qquad ( 46 )$$

If equation (45) and an example shown in FIG. 5 are observed, it is seen that equation (45) according to the invention of the earlier filed application calculates the eight rotation vectors shown in FIG. 5 using all four normalized voltage amplitude symmetric groups defined below.

(a) Normalized voltage amplitude symmetric group 1 v(t), v(t−2T), v(t−4T)
(b) Normalized voltage amplitude symmetric group 2 v(t−T), v(t−3T), v(t−5T)
(c) Normalized voltage amplitude symmetric group 3 v(t−2T), v(t−4T), v(t−6T)
(d) Normalized voltage amplitude symmetric group 4 v(t−3T), v(t−5T), v(t−7T)

In other words, a calculation equation of equation (46) is an example in which the rotation phase angle is set to “2α” in the method of this application. In this way, the concept of the normalized voltage amplitude symmetric group clarified in the invention of this application can be considered a new concept including even the concept of the invention of the earlier filed application.

On the other hand, the invention of this application does not have the concept of the sampling division number present in the invention of the earlier filed application. It is very important that the sampling division number is unnecessary. For example, in the case of the invention of the earlier filed application, a sine value (=sin(Nα)) with respect to a product of the sampling division number N and the rotation phase angle α is calculated. However, when Nα exceeds 180 degrees, because a value of sin(Nα) is negative, an absolute value has to be calculated. In other words, in the invention of the earlier filed application, it has to be always determined whether Nα exceeds 180 degrees. This is a burden in calculation processing. On the other hand, the invention of this application has an advantage that such determination processing is unnecessary and a burden of calculation processing is smaller than that of the invention of the earlier filed application.

Subsequently, calculation equations for measuring representative alternating-current electric quantities (a real voltage amplitude, a real current amplitude, a real frequency, a real active power, a real reactive power, etc.) are explained.

To return to the former explanation, the “real voltage amplitude” is a true value of an alternating-current voltage amplitude. The word “real” is added to distinguish the “real voltage amplitude” from the “normalized voltage amplitude” used in the above explanation (the same applies to the other alternating-current electric quantities). The normalized voltage amplitude is a voltage amplitude calculated using the normalized amplitude symmetric group on the complex plane and is a numerical value having dependency on the frequency of an alternating-current voltage. However, the real voltage amplitude is a numerical value not having dependency on the frequency of an alternating-current voltage.

First, the real voltage amplitude is calculated from equation (7) as indicated by the following equation:

$$V = \frac{{V}_{f}}{sin α} \qquad ( 47 )$$

The real voltage amplitude can be calculated from equation (12) as indicated by the following equation:

$$V = \frac{{V}_{f 2}}{2 sin α sin \frac{α}{2}} \qquad ( 48 )$$

The rotation phase angle α in equations (47) and (48) is calculated using equation (14). However, if a real frequency of a voltage waveform is assumed as being known (e.g., the commercial frequency), a rotation phase angle corresponding thereto can be calculated as indicated by the following equation using the real frequency f and the sampling frequency fₛ. In this case, if one of a normalized voltage amplitude and a normalized chord length is calculated, a real voltage amplitude can be calculated.

$$α = \frac{2 π f}{{f}_{s}} \qquad ( 49 )$$

Because the normalized voltage chord length is calculated using a difference of a voltage instantaneous value, the influence of a direct-current component of the voltage instantaneous value on a measurement value is small. Therefore, when the influence of the direct-current component of the voltage instantaneous value is large, it is more desirable to use equation (48) rather than equation (47).

Subsequently, a method of calculating the real current amplitude is explained. First, in the same manner as the calculation of the normalized voltage amplitude, the calculation equation for the normalized current amplitude is defined as indicated by the following equation:

$${I}_{f} = \sqrt{\frac{1}{n - 2} ( {\sum }_{k = 2}^{n - 1} ( {i}_{k}^{2} - {i}_{k - 1} {i}_{k + 1} ) )} = I sin α , n \geq 3 \qquad ( 50 )$$

Time series data of a current instantaneous value and a current rotation vector are as indicated by the following equations:

iₖ=Re{i[t−(k−1)T]}, k=1, 2, . . . , n (51)

i[t−(k−1)T]=Ie^{j[ωt-(k-1)α]}, k=1, 2, . . . , n (52)

An electric current and a voltage are considered to oscillating at a same frequency. Therefore, a real current amplitude I is calculated as indicated by the following equation using a normalized current amplitude I_{f} and the rotation phase angle α:

$$I = \frac{{I}_{f}}{sin α} \qquad ( 53 )$$

When voltage instantaneous value data is not measured and only current instantaneous value data is measured, a real frequency can be assumed as being known as in the above explanation or a rotation phase angle can be calculated by a same procedure as the calculation method concerning the real voltage amplitude. In the latter case, it is possible to calculate a normalized current amplitude using the normalized current amplitude symmetric group, calculate a normalized current chord length using the normalized current chord length symmetric group, and calculate a rotation phase angle using the normalized current amplitude and the normalized current chord length.

The real current amplitude can be calculated as indicated by the following equation using the normalized current chord length as in the calculation of the real voltage amplitude:

$$I = \frac{{I}_{f 2}}{2 sin α sin \frac{α}{2}} \qquad ( 54 )$$

Because the normalized current chord length is calculated using a difference of a current instantaneous value, the influence of a direct-current component of the current instantaneous value on a measurement value is small. Therefore, when the influence of the direct-current component of the current instantaneous value is large, it is more desirable to use equation (53) rather than equation (52).

The real frequency f can be calculated using equations (14) and (16). Specifically, it is sufficient to calculate the rotation phase angle α according to equation (14) using the normalized voltage amplitude V_{f} and the normalized voltage chord length V_{f2} and calculate the real frequency f according to equation (16) using the calculated rotation phase angle α. The real frequency f smaller than fₛ/2 can be calculated by only this method.

On the other hand, with a real frequency in a range of fₛ/2 to fₛ, a false frequency indicated by the following equation is obtained:

fₐ₁=fₛ−f (55)

In equation (55), fₐ₁ represents a measurement result and f represents a true value of the real frequency.

However, if the real frequency f does not exceed the sampling frequency fₛ and the sampling frequency fₛ can be changed, the true value of the real frequency can be calculated by a procedure explained below.

First, when conditions explained below are satisfied, the real frequency f is smaller than fₛ/2.

(a1) The rotation phase angle increases when the sampling frequency is increased.
(a2) The rotation phase angle decreases when the sampling frequency is reduced.

On the other hand, when conditions explained below are satisfied, the real frequency f is within the range of fₛ/2 to fₛ.

(b1) The rotation phase angle decreases when the sampling frequency is increased.
(b2) The rotation phase angle increases when the sampling frequency is reduced.

Therefore, when it can be determined that the real frequency f is within the range of fₛ/2 to fₛ, the real frequency f can be calculated using the following equation.

f=fₛ−fₐ₁ (56)

Subsequently, a method of calculating the real active power and the real reactive power is explained. FIG. 6 is a diagram of an example of a voltage vector, a current vector, and a power vector arranged on the complex plane. In FIG. 6, the voltage vector and the current vector on the complex plane are respectively represented by the following equations:

v=Ve^{jφ} (57)

i=Ie^{-jφ} (58)

In equation (57) and (58), φ represents a phase angle of the voltage vector formed when a real axis is set as a reference axis and θ represents a phase angle of the current vector formed when the real axis is set as the reference axis (in the example shown in FIG. 6, θ is set on the lower side of the real axis).

A conjugate complex number of the current vector is as indicated by the following equation:

i*=Ie^{jθ} (59)

Electric power is a conjugate integration of the voltage vector and the current vector as indicated by the following equation:

vi*=VIe^{j(φ+θ)} (60)

Therefore, an effective value of the real active power (hereinafter simply referred to as “real active power”) is calculated as indicated by the following equation:

P=Re(vi*)=VI cos(φ+θ)=VI cos φ (61)

Similarly, an effective value of the real reactive power (hereinafter simply referred to as “real reactive power”) is calculated as indicated by the following equation:

Q=Im(vi*)=VI sin(φ+θ)=VI sin φ (62)

φ shown in equations (61) and (62) represents a phase angle between the voltage vector and the current vector and has a relation of the following equation. To supplement the explanation, the character “φ (psi)” in the phase angle φ corresponds to a small letter “φ: phi” of Times New Roman font in the figures and the equations. The notation concerning “φ (psi)” is the same in the following paragraph texts.

φ=φ+θ (63)

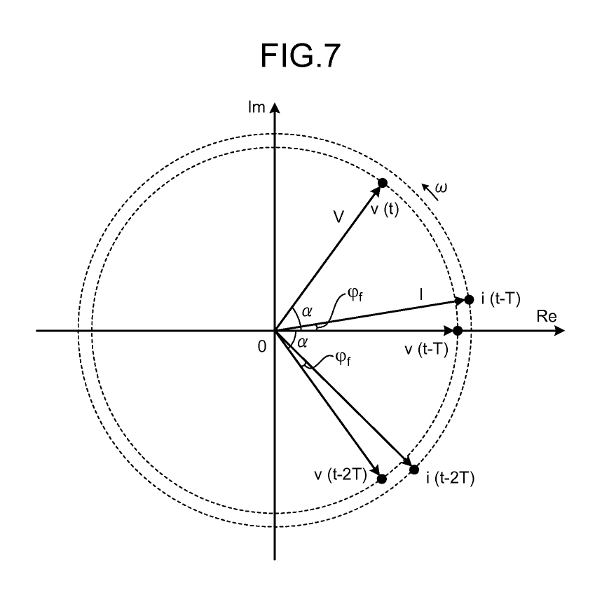

FIG. 7 is a diagram of a normalized power symmetric group on the complex plane. In FIG. 7, three voltage rotation vectors and two current rotation vectors are shown.

First, the three voltage rotation vectors arranged on the complex plane can be represented by the following equation:

$$\begin{matrix}v ( t ) = V {e}^{j ( ω t + α )} \\ v ( t - T ) = V {e}^{j ( ω t )} \\ v ( t - 2 T ) = V {e}^{j ( ω t - α )}\end{matrix} \} \qquad ( 64 )$$

Similarly, the two current rotation vectors arranged on the complex plane can be represented by the following equation:

$$\begin{matrix}i ( t - T ) = I {e}^{j ( ω t + {ϕ}_{f} )} \\ i ( t - 2 T ) = I {e}^{j ( ω t - α + {ϕ}_{f} )}\end{matrix} \} \qquad ( 65 )$$

The three voltage rotation vectors and the two current vectors are defined as a normalized power symmetric group. Four rotation vectors v(t), v(t−T), i(t−T), and i(t−2T) among these rotation vectors are defined as a normalized active power symmetric group. Further, the normalized active power is defined as indicated by the following equation using the normalized active power symmetric group:

P_{f}=v₂i₂−v₁v₃ (66)

In equation (66), a voltage instantaneous value and a current instantaneous value shown in the equation are respectively a real part of the voltage rotation vector and a real part of the current rotation vector and are calculated as indicated by the following equations:

$$\begin{matrix}\begin{matrix}{v}_{1} = Re [ v ( t ) ] = V cos ( ω t + α ) \\ {v}_{2} = Re [ v ( t - T ) ] = V cos ( ω t )\end{matrix} \} & ( 67 ) \\ \begin{matrix}{i}_{2} = Re [ i ( t - T ) ] = I cos ( ω t + {ϕ}_{f} ) \\ {i}_{3} = Re [ i ( t - 2 T ) ] = I cos ( ω t - α + {ϕ}_{f} )\end{matrix} \} & ( 68 )\end{matrix}$$

When the voltage instantaneous value and the current instantaneous value indicated by equations (67) and (68) are substituted in equation (66), equation (66) is expanded as indicated by the following equation.

$$\begin{matrix}\begin{matrix}{P}_{f} = {v}_{2} {i}_{2} - {v}_{1} {i}_{3} \\ = VI [ cos ( ω t ) cos ( ω t + {ϕ}_{f} ) - \\ cos ( ω t + α ) cos ( ω t - α + {ϕ}_{f} ) ] \\ = \frac{VI}{2} [ cos ( 2 ω t + {ϕ}_{f} ) + cos {ϕ}_{f} - \\ cos ( 2 ω t + {ϕ}_{f} ) - cos ( 2 α - {ϕ}_{f} ) ] \\ = \frac{VI}{2} [ cos {ϕ}_{f} ( 1 - cos 2 α ) - sin ( 2 α ) sin {ϕ}_{f} ] \\ = VI sin α sin ( α - {ϕ}_{f} )\end{matrix} \\ \end{matrix} \} \qquad ( 69 )$$

In other words, a normalized active power P_{f} is represented by the following equation:

P_{f}=VI sin α sin(α−φ_{f}) (70)

Because the frequency f and the rotation phase angle α correspond in a one-to-one relation, the normalized active power P_{f} corresponding to a fixed frequency is a fixed value. A relation between the normalized active power P_{f} and the frequency f is converted into a relation between the normalized active power P_{f} and the rotation phase angle α and normalized voltage-to-current phase angle φ_{f}.

Four rotation vectors v(t−T), v(t−2T), i(t−T), and i(t−2T) are defined as a normalized reactive power symmetric group. The normalized reactive power is defined as indicated by the following equation using the normalized reactive power symmetric group:

Q_{f}=v₃i₂−v₂v₃ (71)

In equation (71), a voltage instantaneous value shown in the equation is a real part of the voltage rotation vector and calculated as indicated by the following equation:

$$\begin{matrix}{v}_{2} = Re [ v ( t - T ) ] = V cos ( ω t ) \\ {v}_{3} = Re [ v ( t - 2 T ) ] = V cos ( ω t + α )\end{matrix} \} \qquad ( 72 )$$

When a voltage instantaneous value indicated by equation (72) and a current instantaneous value indicated by equation (68) are substituted in equation (71), equation (71) is expanded as indicated by the following equation:

$$\begin{matrix}\begin{matrix}{Q}_{f} = {v}_{3} {i}_{2} - {v}_{2} {i}_{3} \\ = VI [ cos ( ω t - α ) cos ( ω t + {ϕ}_{f} ) - \\ cos ( ω t ) cos ( ω t - α + {ϕ}_{f} ) ] \\ = \frac{VI}{2} [ cos ( 2 ω t - α + {ϕ}_{f} ) + cos ( α + {ϕ}_{f} ) - \\ cos ( 2 ω t - α + {ϕ}_{f} ) - cos ( α - {ϕ}_{f} ) ] \\ = \frac{VI}{2} [ cos ( α + {ϕ}_{f} ) - cos ( α - {ϕ}_{f} ) ] \\ = - VI sin α sin {ϕ}_{f}\end{matrix} \\ \end{matrix} \} \qquad ( 73 )$$

In other words, a normalized reactive power Q_{f} is represented by the following equation:

Q_{f}=Vi sin α sin φ_{f} (74)

Because the frequency f and the rotation phase angle α correspond in a one-to-one relation, the normalized reactive power Q_{f} corresponding to a fixed frequency is a fixed value. A relation between the normalized reactive power Q_{f} and the frequency f is converted into a relation between the normalized reactive power Q_{f} and the rotation phase angle α and normalized voltage-to-current phase angle φ_{f}.

Subsequently, a method of calculating a normalized voltage-to-current phase angle is explained. First, in equation (70), when a sine term concerning a deviation between the rotation phase angle α and the normalized voltage-to-current phase angle φ_{f} is expanded and both the sides of equation (74) are multiplied by (−cos(α)), equation (70) is transformed as indicated by the following equation:

$$\begin{matrix}{P}_{f} = VI {sin}^{2} α cos {ϕ}_{f} - VI sin α cos α sin {ϕ}_{f} \\ {Q}_{f} \times ( - cos α ) = VI sin α cos α sin {ϕ}_{f}\end{matrix} \} \qquad ( 75 )$$

The normalized voltage-to-current phase angle φ_{f} can be calculated from equation (75) using the following equation:

$${ϕ}_{f} = {cos}^{- 1} ( \frac{{P}_{f} - {Q}_{f} cos α}{VI {sin}^{2} α} ) \qquad ( 76 )$$

The real voltage-to-current phase angle φ can be calculated using the following equation. The real voltage-to-current phase angle φ is explained in detail in a section of a simulation result explained below.

$$ϕ = \{ \begin{matrix}{ϕ}_{f} , {Q}_{f} \leq 0 \\ - {ϕ}_{f} , {Q}_{f} > 0\end{matrix} \qquad ( 77 )$$

The normalized voltage-to-current phase angle φ_{f} can be calculated using another calculation equation. For example, if a ratio of both the sides is calculated between equation (70) and equation (74), the following equation is obtained.

$$\frac{{P}_{f}}{{Q}_{f}} = \frac{VI sin α sin ( α - {ϕ}_{f} )}{- VI sin α sin {ϕ}_{f}} = \frac{sin ( α - {ϕ}_{f} )}{- sin {ϕ}_{f}} \qquad ( 78 )$$

If the right side of equation (78) is expanded and the equation is put in order using tan(φ_{f}), the following equation is obtained:

$${ϕ}_{f} = {tan}^{- 1} ( \frac{sin α}{\frac{{P}_{f}}{{Q}_{f} - cos α}} ) \qquad ( 79 )$$

In this way, the normalized voltage-to-current phase angle φ_{f} can be calculated using equation (79) other than equation (76).

The real voltage-to-current phase angle φ can be calculated using the following equation. The real voltage-to-current phase angle φ is explained in detail in the section of a simulation result explained below.

$$ϕ = \{ \begin{matrix}{ϕ}_{f} , & {Q}_{f} \leq 0 \\ 180 - {ϕ}_{f} , & {Q}_{f} > 0\end{matrix} \qquad ( 80 )$$

Further, the real active power can be calculated from equation (81) and the real reactive power can be calculated from equation (82).

P=VI cos φ (81)

Q=VI sin φ (82)

The real voltage amplitude V can be calculated from equation (47) or (48). The real current amplitude I can be calculated from equation (53) or (54). The real voltage-to-current phase angle φ can be calculated from equation (77) or (80).

In FIG. 7, a voltage vector and a current vector are arranged on the complex plane in relation to a frequency (the rotation phase angle α). A phase difference between the current vector and the voltage vector at the same time (the same sampling time) is the normalized voltage-to-current phase angle φ_{f}. The normalized voltage-to-current phase angle φ_{f} is represented as indicated by equations (76) and (79) using an inverse cosine function or an inverse tangent function. On the other hand, because the inverse cosine function or the inverse tangent function is a multi-valued function, the normalized voltage-to-current phase angle φ_{f} is not always equal to the real voltage-to-current phase angle φ (see FIG. 6). The normalized voltage-to-current phase angle φ_{f} and the real voltage-to-current phase angle φ are similar elements in different phase spaces. However, a normalized voltage-to-current phase angle can be changed to a real voltage-to-current phase angle with simple correction equations. equations (77) and (80) correspond to the correction equations.

In FIG. 7, as an example of a normalized power symmetric group, the current vector is more advanced in phase than the voltage vector. However, the current vector can be more delayed in phase than the voltage vector. In this case, the same calculation result is obtained.

In the calculation of the normalized active power and the normalized reactive power, in the calculation example explained above, the real parts (the cosine functions) of the voltage rotation vector and the current rotation vector are used as the voltage instantaneous value and the current instantaneous value. However, it is also naturally possible to use imaginary parts (sine functions) of the rotation vectors as the voltage instantaneous value and the current instantaneous value. In these cases, it is possible to obtain the real voltage-to-current phase angle based on the normalized voltage-to-current phase angle using correction equations respectively corresponding thereto.

Subsequently, a method of calculating a normalized active power by increasing the number of sampling points is presented. A basic idea is the same as the basic idea for the normalized voltage amplitude and the normalized voltage chord length.

First, a calculation equation for a normalized active power by a normalized active power symmetric group defined by n (the number of sampling points is n) voltage rotation vectors or current rotation vectors can be generalized as follows:

$${P}_{f} = \frac{1}{n - 2} ( {\sum }_{k = 2}^{n - 1} ( {v}_{k} {i}_{k} - {v}_{k - 1} {i}_{k + 1} ) ) = VI sin α sin ( α - {ϕ}_{f} ) , \\ n \geq 3 \qquad ( 83 )$$

Time series data of the voltage instantaneous value and the current instantaneous value is as indicated by the following equations.

$$\begin{matrix}{v}_{k} = Re \{ v [ t - ( k - 1 ) T ] \} , k = 1 , 2 , … , n \\ {i}_{k} = Re \{ i [ t - ( k - 1 ) T ] \} , k = 1 , 2 , … , n\end{matrix} \} \qquad ( 84 )$$

Time series data of the voltage rotation vector and the current rotation vector are as indicated by the following equations:

$$\begin{matrix}v [ t - ( k - 1 ) T ] = V {e}^{j [ ω t - ( k - 1 ) α ]} , k = 1 , 2 , … , n \\ i [ t - ( k - 1 ) T ] = I {e}^{j [ ω t - ( k - 1 ) α + {ϕ}_{f} ]} , k = 1 , 2 , … , n\end{matrix} \} \qquad ( 85 )$$

Similarly, a calculation equation for a normalized reactive power by a normalized reactive power symmetric group defined by n+1 (the number of sampling points is n+1) voltage rotation vectors and current rotation vectors can be also generalized as follows:

$${Q}_{f} = \frac{1}{n - 2} ( {\sum }_{k = 2}^{n - 1} ( {v}_{k + 1} {i}_{k} - {v}_{k} {i}_{k + 1} ) ) = - VI sin α sin {ϕ}_{f} , \\ n \geq 3 \qquad ( 86 )$$

The normalized voltage-to-current phase angle and the real voltage-to-current phase angle can be calculated using equations (76) and (77) or equations (79) and (80).

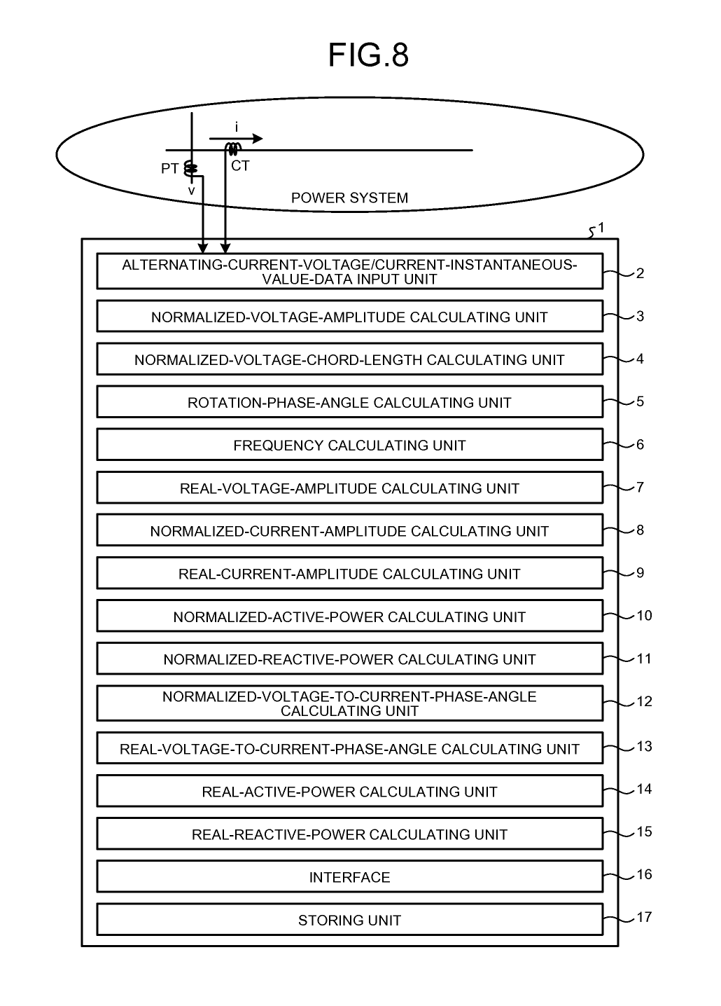

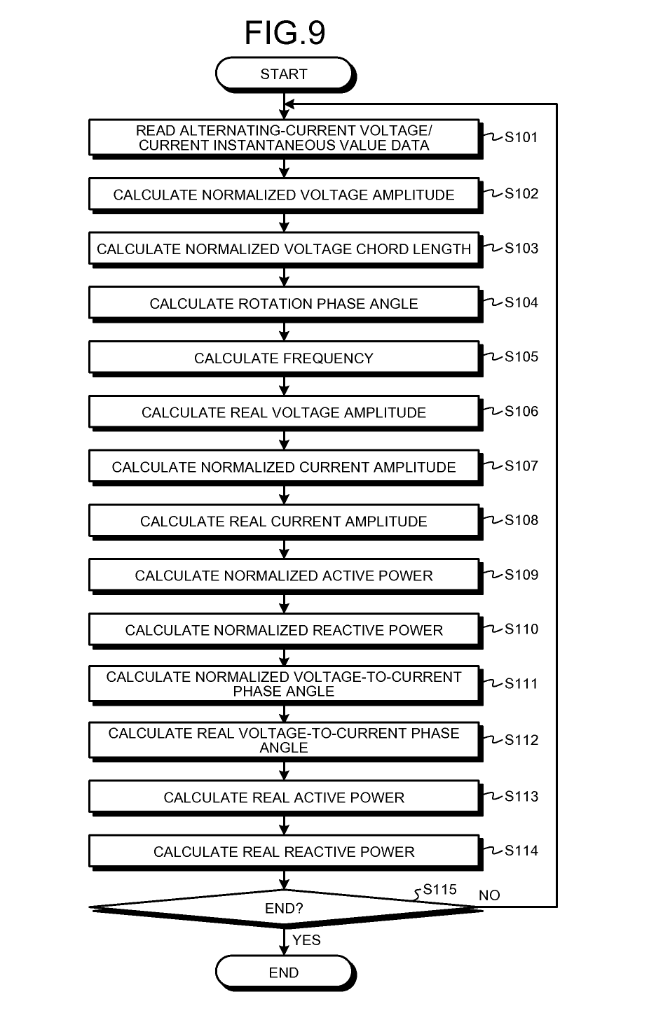

A functional configuration and an operation of an alternating-current electric quantity measuring apparatus according to this embodiment are explained with reference to FIGS. 8 and 9. FIG. 8 is a diagram of a functional configuration of an alternating-current electric quantity measuring apparatus 1 according to this embodiment. FIG. 9 is a flowchart for explaining a flow of processing in the alternating-current electric quantity measuring apparatus 1.

As shown in FIG. 8, the alternating-current electric quantity measuring apparatus 1 according to this embodiment includes an alternating-current-voltage/current-instantaneous-value-data input unit 2, a normalized-voltage-amplitude calculating unit 3, a normalized-voltage-chord-length calculating unit 4, a rotation-phase-angle calculating unit 5, a frequency calculating unit 6, a real-voltage-amplitude calculating unit 7, a normalized-current-amplitude calculating unit 8, a real-current-amplitude calculating unit 9, a normalized-active-power calculating unit 10, a normalized-reactive-power calculating unit 11, a normalized-voltage-to-current-phase-angle calculating unit 12, a real-voltage-to-current-phase-angle calculating unit 13, a real-active-power calculating unit 14, a real-reactive-power calculating unit 15, an interface 16, and a storing unit 17. The interface 16 performs processing for outputting a calculation result and the like to a display apparatus and an external apparatus. The storing unit 17 performs processing for storing measurement data, the calculation result, and the like.

In the configuration explained above, the alternating-current-voltage/current-instantaneous-value-data input unit 2 performs processing for capturing a voltage instantaneous value and a current instantaneous value from a metering potential transformer (PT) and a current transformer (CT) provided in a power system (step S101). Data of the captured voltage instantaneous value and current instantaneous value are stored in the storing unit 17.

The normalized-voltage-amplitude calculating unit 3 calculates a normalized voltage amplitude using a plurality of predetermined voltage instantaneous value data included in the normalized voltage amplitude symmetric group (step S102). To comprehensively explain calculation processing for the normalized voltage amplitude as well as the concept of the algorithm explained above, the calculation processing can be explained as follow. To satisfy a sampling theorem, the normalized-voltage-amplitude calculating unit 3 performs processing for normalizing, with an amplitude value of an alternating-current voltage, a voltage amplitude calculated by, for example, a square integral operation of at least three instantaneous values continuously sampled at a sampling frequency twice or higher than a frequency of an alternating-current voltage to be measured and calculating the voltage amplitude as a normalized voltage amplitude.

The normalized-voltage-chord-length calculating unit 4 calculates a normalized voltage chord length using a plurality of predetermined voltage instantaneous value data included in the normalized voltage chord length symmetric group (step S103). The normalized-voltage-chord-length calculating unit 4 can be comprehensively explained as follows. The normalized-voltage-chord-length calculating unit 4 performs processing for normalizing, with an amplitude value of an alternating-current voltage, a voltage chord length calculated by, for example, the square integral operation of three instantaneous values (voltage chord length instantaneous values) representing an end-to-end distance between adjacent two instantaneous values among at least four continuous instantaneous values including the three instantaneous values, which are sampled at the sampling frequency and used in calculating the normalized voltage amplitude, and calculating the voltage chord length as a normalized voltage chord length.

The rotation-phase-angle calculating unit 5 calculates a rotation phase angle corresponding to one period of sampling using the normalized voltage amplitude calculated by the normalized-voltage-amplitude calculating unit 3 and the normalized voltage chord length calculated by the normalized-voltage-chord-length calculating unit 4 (step S104). A calculation equation for the rotation phase angle is as indicated by equation (14) and the like.

The frequency calculating unit 6 calculates a frequency of the power system using the rotation phase angle calculated by the rotation-phase-angle calculating unit 5 and a sampling period (step S105). A calculation equation for calculating the frequency is as indicated by equation (17) and the like.

The real-voltage-amplitude calculating unit 7 calculates a real voltage amplitude, which is a true value of an alternating-current voltage amplitude, using the normalized voltage amplitude calculated by the normalized-voltage-amplitude calculating unit 3 and the rotation phase angle calculated by the rotation-phase-angle calculating unit 5 (step S106). A calculation equation for the real voltage amplitude is as indicated by equations (47) and (48) and the like.

The normalized-current-amplitude calculating unit 8 calculates a normalized current amplitude using a plurality of predetermined current instantaneous value data included in the normalized current amplitude symmetric group (step S107). To satisfy the sampling theorem, the normalized-current-amplitude calculating unit 8 performs processing for normalizing, with an amplitude value of an alternating current, a current amplitude calculated by, for example, the square integral operation of at least three instantaneous values continuously sampled at a sampling frequency twice or higher than a frequency of an alternating current to be measured and calculating the current amplitude as a normalized current amplitude.

The real-current-amplitude calculating unit 9 calculates a real current amplitude, which is a true value of an alternating current amplitude, using the normalized current amplitude calculated by the normalized-current-amplitude calculating unit 8 and the rotation phase angle calculated by the rotation-phase-angle calculating unit 5 (step S108). A calculation equation for the real current amplitude is as indicated by equation (53) and (54) and the like.

The normalized-active-power calculating unit 10 calculates a normalized active power using a plurality of predetermined voltage instantaneous values and a plurality of predetermined current instantaneous values included in the normalized power symmetric group (step S109). More specifically, the normalized-active-power calculating unit 10 calculates the normalized active power by performing, for example, the square integral operation of a product (a voltage/current product) of two predetermined voltage instantaneous values selected from three predetermined voltage instantaneous values continuously sampled at a sampling frequency twice or higher than a frequency of an alternating-current voltage to be measured and two predetermined current instantaneous values selected from three current instantaneous values sampled at a sampling frequency twice or higher than a frequency of an alternating current to be measured and sampled at the same times as the three predetermined voltage instantaneous values (see equations (66) and (83) and the like).

The normalized-reactive-power calculating unit 11 calculates a normalized reactive power using a plurality of predetermined voltage instantaneous values and a plurality of predetermined current instantaneous values included in the normalized power symmetric group (step S110). More specifically, the normalized-reactive-power calculating unit 11 calculates the normalized reactive power by performing, for example, the square integral operation of a product (a voltage/current product) of two predetermined voltage instantaneous values selected from three predetermined voltage instantaneous values continuously sampled at a sampling frequency twice or higher than a frequency of an alternating-current voltage to be measured and two predetermined current instantaneous values continuously selected from three current instantaneous values sampled at a sampling frequency twice or higher than a frequency of an alternating current to be measured and sampled at the same times as the three predetermined voltage instantaneous values (see equations (71) and (86) and the like).

The normalized-voltage-to-current-phase-angle calculating unit 12 calculates a normalized voltage-to-current phase angle using the normalized active power calculated by the normalized-active-power calculating unit 10, the normalized reactive power calculated by the normalized-reactive-power calculating unit 11, and the rotation phase angle calculated by the rotation-phase-angle calculating unit 5 (step S111). A calculation equation for the normalized voltage-to-current phase angle is as indicated by equations (76) and (79) and the like.

The real-voltage-to-current-phase-angle calculating unit 13 calculates a real voltage-to-current phase angle, which is a true value of an alternating-current voltage-to-current phase angle, using the normalized voltage-to-current phase angle calculated by the normalized-voltage-to-current-phase-angle calculating unit 12 and the frequency calculated by the frequency calculating unit 6 (step S112). A calculation equation for the real voltage-to-current phase angle is as indicated by equations (77) and (80) and the like.

The real-active-power calculating unit 14 calculates a real active power, which is a true value of an active power, using the real voltage amplitude calculated by the real-voltage-amplitude calculating unit 7, the real current amplitude calculated by the real-current-amplitude calculating unit 9, and the real voltage-to-current phase angle calculated by the real-voltage-to-current-phase-angle calculating unit 13 (step S113). A calculation equation for the real active power is as indicated by equation (81) and the like.

The real-reactive-power calculating unit 15 calculates a real reactive power, which is a true value of a reactive power, using the real voltage amplitude calculated by the real-voltage-amplitude calculating unit 7, the real current amplitude calculated by the real-current-amplitude calculating unit 9, and the real voltage-to-current phase angle calculated by the real-voltage-to-current-phase-angle calculating unit 13 (step S114). A calculation equation for the real reactive power is as indicated by equation (82) and the like.

At the last step S115, the alternating-current electric quantity measuring apparatus 1 performs processing for determining whether the overall flow explained above is ended. If the flow is not ended (No at step S115), the alternating-current electric quantity measuring apparatus 1 repeatedly perform the processing at steps S101 to S114.

Subsequently, results of simulations applied to the alternating-current electric quantity measuring apparatus according to this embodiment are explained. Table 1 below is a table of parameters during execution of a first simulation. In this simulation, as shown in Table 1, a real frequency is a non-integer.

TABLE 1
Parameters in First Simulation

| | | | | Initial |
|---|---|---|---|---|
| | | | | phase |
| | Number of | | Amplitude | angle of |
| Sampling | sampling | Real | of input | input |
| frequency | points | frequency | voltage | voltage |
| 200 Hz | 4 | 62.07 Hz | 1 V | 20 DEG |

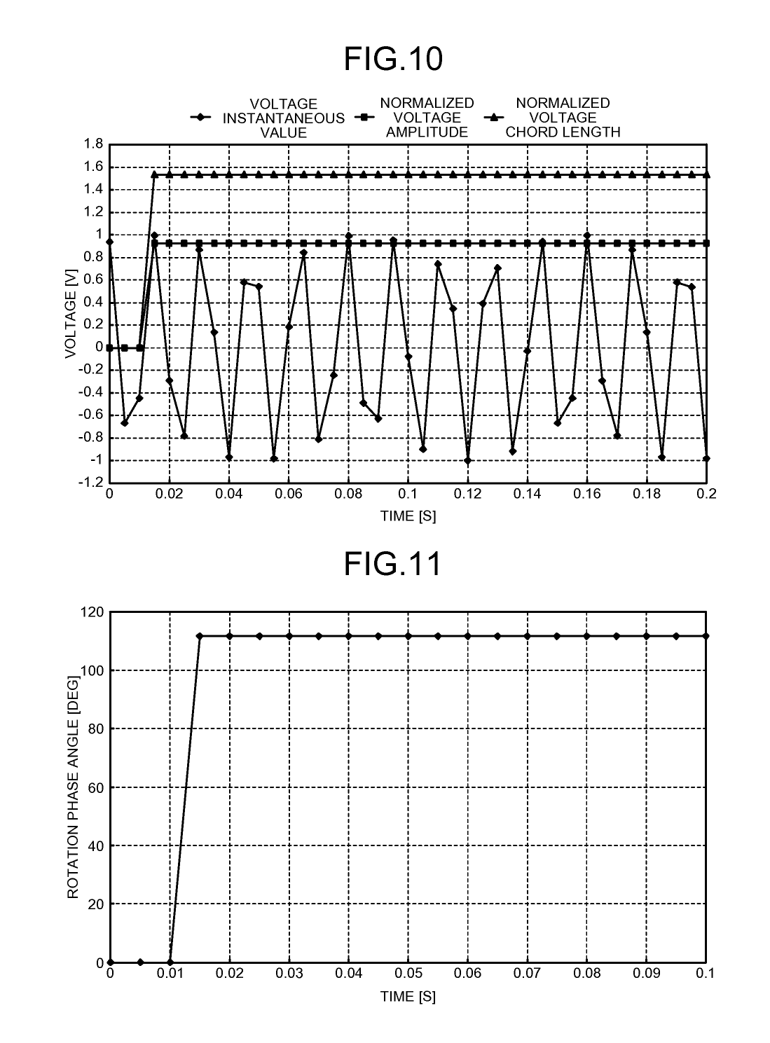

FIG. 10 is a graph of a waveform of a voltage instantaneous value during the execution of the first simulation and a normalized voltage amplitude and a normalized chord length calculated based on the voltage instantaneous value. In FIG. 10, a waveform connecting black diamond signs represents the voltage instantaneous value, a waveform connecting black square signs represents the normalized voltage amplitude, and a waveform connecting black triangle signs represents the normalized voltage chord length.

When the normalized voltage amplitude is calculated using sampling points v₂, v₃, and v₄ at arbitrary four sampling points (“v₁, v₂, v₃, and v₄”) in the voltage instantaneous value waveform shown in FIG. 10, a value shown below is obtained. The value of the normalized voltage amplitude obtained at this point is fixed irrespective of a sampling point (see the waveform of the black square signs shown in FIG. 10).

V_{f1}=\sqrt{v₃²−v₂v₄}=0.92896 (V) (87)

When the normalized voltage chord length is calculated using the four sampling points v₁, v₂, v₃, and v₄, a value shown below is obtained. The value of the normalized voltage chord length obtained at this point is also fixed irrespective of a sampling point (see the waveform of the black triangle signs shown in FIG. 10).

$$\begin{matrix}{V}_{f 2} = \sqrt{{v}_{22}^{2} - {v}_{21} {v}_{23}} \\ = \sqrt{{( {v}_{3} - {v}_{2} )}^{2} - ( {v}_{2} - {v}_{1} ) ( {v}_{4} - {v}_{3} )} \\ = 1.53780 ( V )\end{matrix} \qquad ( 88 )$$

When the rotation phase angle is calculated using the voltage instantaneous value shown in FIG. 10, a value shown below is obtained.

$$α = 2 {sin}^{- 1} ( \frac{{V}_{f 2}}{2 {V}_{f}} ) = 111.726 ( DEG ) \qquad ( 89 )$$

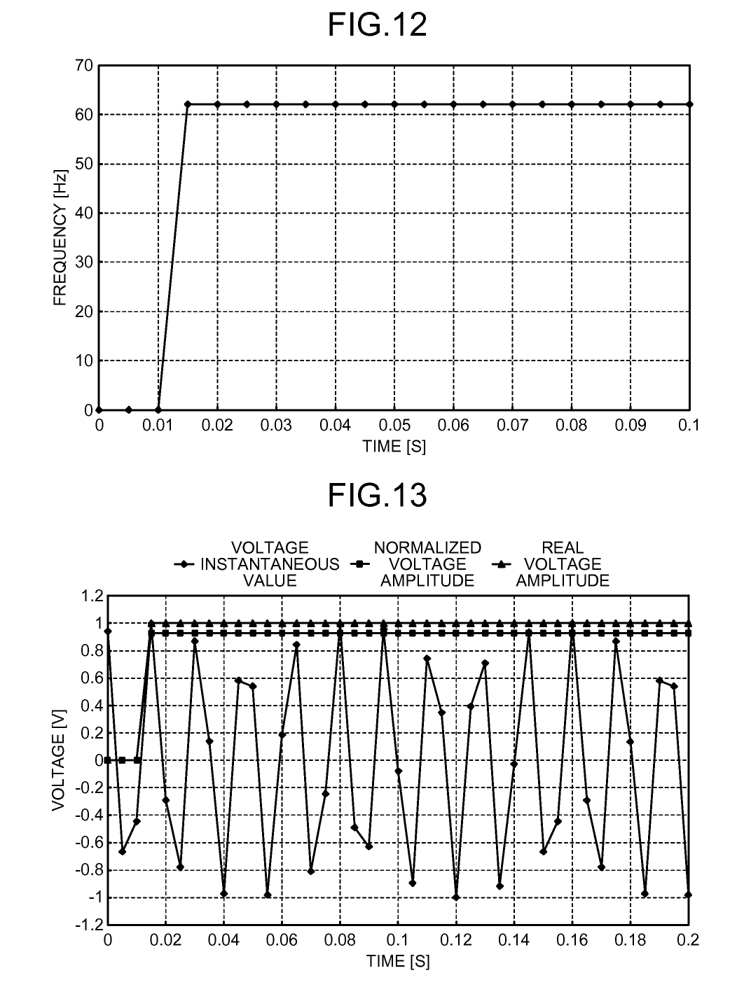

Because the values of the normalized voltage amplitude and the normalized voltage chord length are fixed, a fixed calculation value of the rotation phase angle is obtained as shown in FIG. 11. Because the calculation value of the rotation phase angle is fixed, a fixed calculation value of a real frequency is obtained as shown in FIG. 12 and as indicated by the following equation.

$$f = \frac{α}{2 π T} = \frac{111.726}{360} \times 200 = 62.07 ( Hz ) \qquad ( 90 )$$

As indicated by equation (90), it is seen that a parameter (62.07 hertz) of the real frequency in this simulation shown in Table 1 is correctly calculated.

FIG. 13 is a graph of a real voltage amplitude calculated in the first simulation. From the viewpoint of comparison, a voltage instantaneous waveform and a normalized voltage amplitude same as those shown in FIG. 10 are also shown. In FIG. 13, a waveform connecting black diamond signs represents the voltage instantaneous value, a waveform connecting black square signs represents the normalized voltage amplitude, and a waveform connecting black triangle signs represents the real voltage amplitude.

When the real voltage amplitude is calculated using the value of the normalized voltage amplitude obtained by equation (87) and the value of the rotation phase angle obtained by equation (90), a value shown below is obtained.

$$V = \frac{{V}_{f 1}}{sin α} = \frac{0.92896}{sin ( 112.726 )} = 1 ( V ) \qquad ( 91 )$$

The value of equation (91) coincides with the amplitude value of the input voltage shown in Table 1. In this way, it is seen that, regardless of the fact that the value of the normalized voltage amplitude and the value of the real voltage amplitude are different, the real voltage amplitude is correctly calculated by performing frequency correction based on the rotation phase angle.

In Table 2 shown below, parameters during execution of a second simulation are shown. In this simulation, as shown in Table 2, a sampling frequency is fixed to 1000 hertz and, on the other hand, a real frequency is changed to 0 hertz to 1000 hertz.

TABLE 2
Parameters in Second Simulation

| | | | Initial phase |
|---|---|---|---|
| Sampling | Real | Amplitude of | angle of |
| frequency | frequency | input voltage | voltage |
| 1000 Hz | 0 to 1000 Hz | 1 V | 0 DEG |

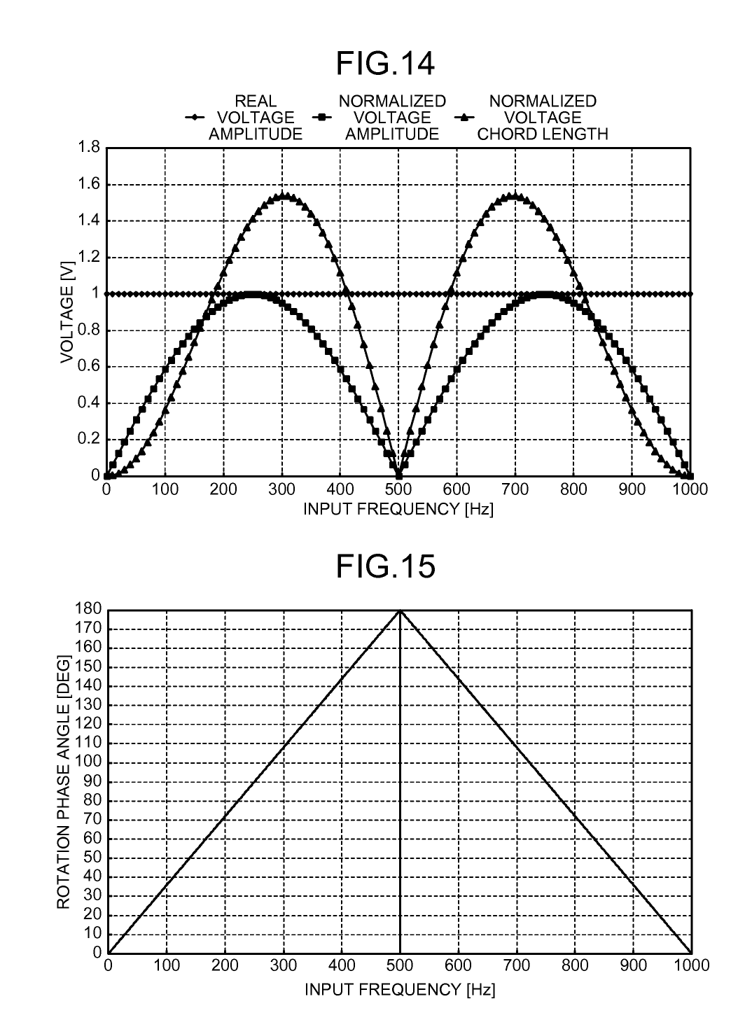

FIG. 14 is a graph of a normalized voltage amplitude, a normalized chord length, and a real voltage amplitude calculated in the second simulation. In FIG. 14, waveform connecting black square signs represents the normalized voltage amplitude, a waveform connecting black triangle signs represents the normalized voltage chord length, and a waveform connecting black diamond signs represents the real voltage amplitude.

As indicated by equation (7) and the like, the normalized voltage amplitude is a product of the real voltage amplitude f and the sine function of the rotation phase angle α. When the rotation phase angle α is 90 degrees (the real frequency f is ¼ of the sampling frequency fₛ), the normalized voltage amplitude V_{f} and the real voltage amplitude V are equal (see FIG. 14). At this point, the normalized voltage amplitude V_{f} is the maximum. At this point, when the normalized voltage chord length is calculated using equation (12), a value shown below is obtained.

$${V}_{f 2} = 2 V sin α sin \frac{α}{2} = 2 \times sin ( 90 ) \times sin ( \frac{90}{2} ) = \sqrt{2} ( V ) \qquad ( 92 )$$

When the rotation phase angle α is 60 degrees, the normalized voltage amplitude and the normalized voltage chord length are equal. Values of the normalized voltage amplitude and the normalized voltage chord length are as shown below.

$${V}_{f} = {V}_{f 2} = V sin α = 2 V sin α sin \frac{α}{2} = sin ( 60 ) = \frac{\sqrt{3}}{2} ( V ) \qquad ( 93 )$$

The normalized voltage chord length V_{f2} is the maximum when the rotation phase angle α is 109.62 degrees and is a value shown below.

$${V}_{f 2} = 2 V sin α sin \frac{α}{2} = 2 \times sin ( 109.62 ) \times sin ( \frac{109.62}{2} ) = 1.53959 ( V ) \qquad ( 94 )$$

The normalized voltage amplitude takes a value of the following equation:

V_{f}=V sin α=sin(109.62)=0.94194 (V) (95)

$$f = \frac{α}{360} {f}_{s} = \frac{109.62}{360} \times 1000 = 304.50 ( Hz ) \qquad ( 96 )$$

FIG. 15 is a graph of a change in the rotation phase angle calculated in the second simulation. It is seen from a waveform shown in FIG. 15 that, when an input frequency (a real frequency) is 0 to fₛ/2, the rotation phase angle α linearly corresponds to the input frequency between 0 degrees to 180 degrees. When the real frequency is fₛ/4 (250 hertz in this simulation), the rotation phase angle α is 90 degrees.

When the real frequency is fₛ/2 (500 hertz in this simulation), because the normalized voltage amplitude and the normalized voltage chord length are simultaneously zero, calculation cannot be performed. Therefore, this point is regarded as a point where calculation is impossible. A value of zero is given to this point

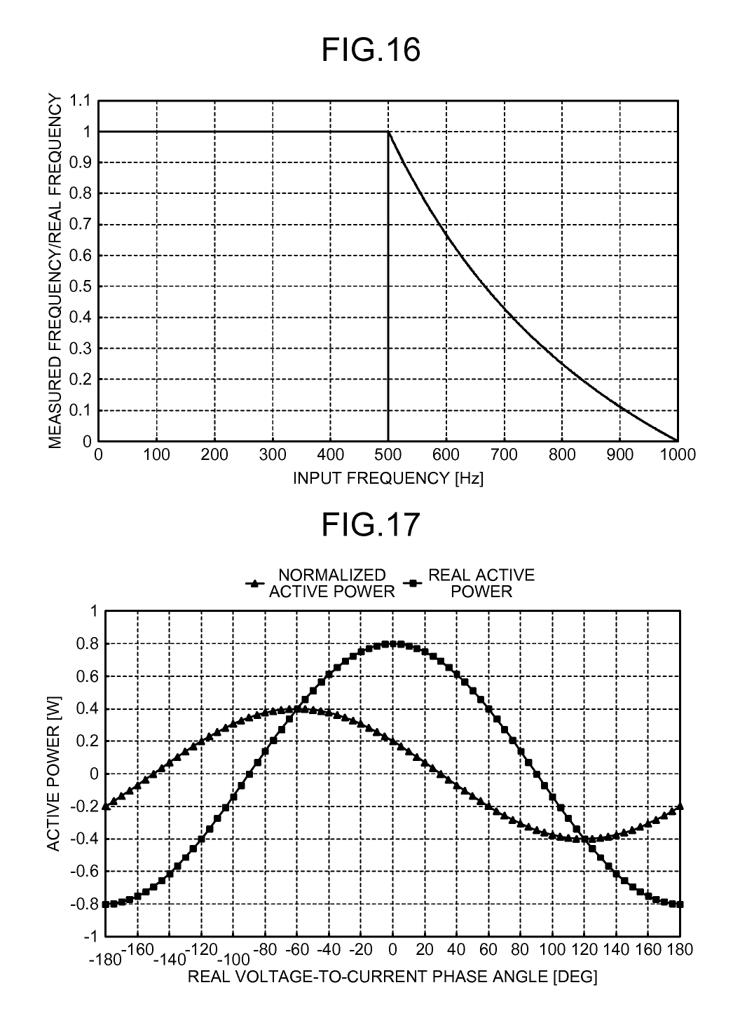

FIG. 16 is a graph of a frequency gain characteristic during the execution of the second simulation. A relation of a frequency ratio (a ratio of a calculated frequency and a real frequency) with respect to the input frequency (the real frequency) is shown. In FIG. 16, when the real frequency is 0 to fₛ/2, the frequency ratio is always 1. In other words, it is seen that, when the real frequency is 0 to fₛ/2, calculation of the real frequency is executed without including an error. As in the case shown in FIG. 15, when the real frequency is fₛ/2 (500 hertz), because both of the normalized voltage amplitude and the normalized voltage chord length are zero, a value of the frequency ratio is set to zero.

In Table 3 below, parameters during execution of a third simulation are shown. In this simulation, as shown in Table 3, and initial phase angle of an input voltage is fixed to 0 degree and, on the other hand, an initial phase angle of an input current is changed between −180 degrees to +180 degrees.

TABLE 3
Parameters in Third Simulation

| | Number of | | Amplitude | Initial phase | Amplitude | Initial phase |
|---|---|---|---|---|---|---|
| Sampling | sampling | Real | of input | angle of input | of input | angle of input |
| frequency | points | frequency | voltage | voltage | current | current |
| 600 Hz | 4 | 50 Hz | 1 V | 0 DEG | 0.8 A | −180 to |
| | | | | | | 180 DEG |

FIG. 17 is a graph of a normalized active power and a real active power calculated in the third simulation. In FIG. 17, a waveform connecting black triangle signs represents the normalized active power and a waveform connecting black square signs represents the real active power.

As shown in FIG. 17, the normalized active power and the real active power have different peak values with respect to a change in a real voltage-to-current phase angle. The real voltage-to-current phase angles at which the normalized active power and the real active power are the peak values are also different values.

In this simulation, because the real frequency is 50 hertz and the sampling frequency is 600 hertz, the rotation phase angle α is 30 degrees (=360/(600/50)). As it can be understood if equation (70) and equation (81) at the rotation phase angle α=30 degrees are compared, the maximum of the normalized active power is ½ of the maximum of the real active power (see the waveforms shown in FIG. 17). When the real frequency is 150 hertz (=fₛ/4), the rotation phase angle α is 90 degrees (=360/(600/150)). The normalized active power and the real active power are equal.

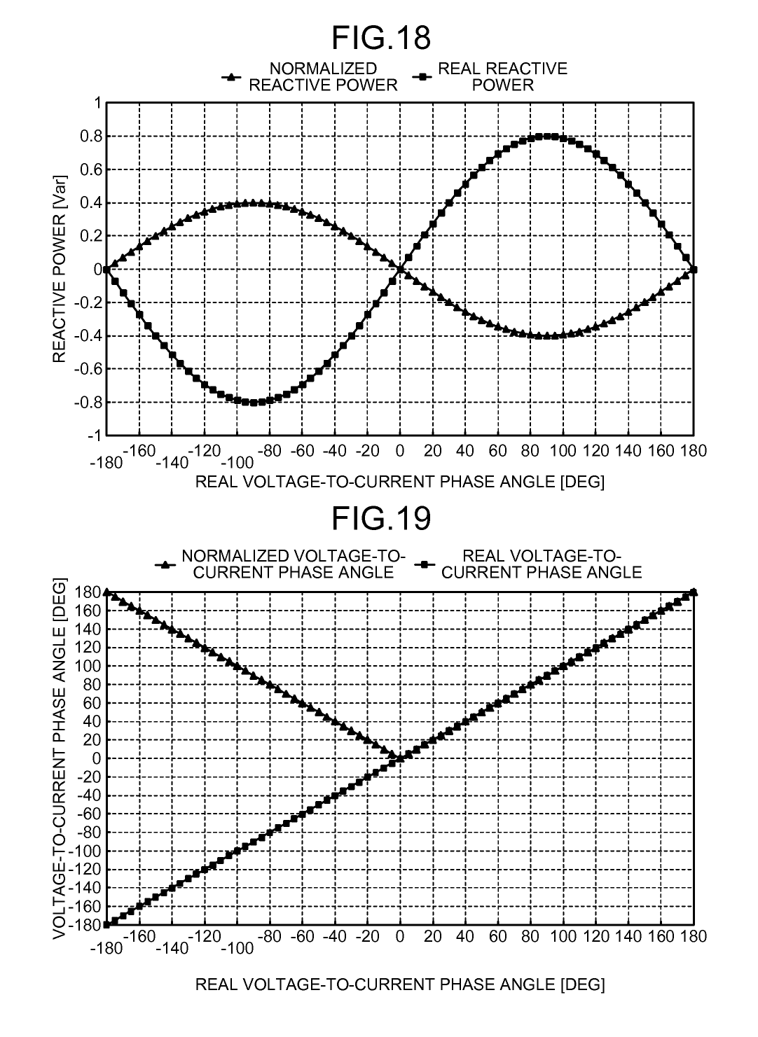

FIG. 18 is a graph of a normalized reactive power and a real reactive power calculated in the third simulation. In FIG. 18, a waveform connecting black triangle signs represents the normalized reactive power and a waveform connecting black square signs represents the real reactive power.

As shown in FIG. 18, signs of the normalized reactive power and the real reactive power are different. In this simulation, as explained above, because the rotation phase angle α is 30 degrees, as it can be understood if equation (74) and equation (82) at the rotation phase angle α=30 degrees are compared, the maximum of the normalized reactive power is ½ of the maximum of the real reactive power (see the waveforms shown in FIG. 18). When the real frequency is 150 hertz (=fₛ/4), the rotation phase angle α is 90 degrees (=360/(600/150)). Absolute values of the normalized reactive power and the real reactive power are equal.

FIG. 19 is a graph of a normalized voltage-to-current phase angle and a real voltage-to-current phase angle calculated in the third simulation. In FIG. 19, a waveform connecting black triangle signs represents the normalized voltage-to-current phase angle and a waveform connecting black square signs represents the real voltage-to-current phase angle.

As shown in FIG. 19, when the real voltage-to-current phase angle is 0 degrees to 180 degrees, the real voltage-to-current phase angle and the normalized voltage-to-current phase angle are equal. In this case, as it is seen from equations (74) and (82), signs of the real reactive power and the normalized reactive power are different.

On the other hand, it is seen that, when the real voltage-to-current phase angle is −180 degrees to 0 degree, absolute values of the normalized voltage-to-current phase angle and the real voltage-to-current phase angle are equal and signs thereof are different. Because of this characteristic, in the correction calculation equation (see equation (77)) for calculating the real voltage-to-current phase angle from the normalized voltage-to-current phase angle, the normalized voltage-to-current phase angle is multiplied with “−1” when a sign of the normalized reactive power is plus. A relation between the normalized voltage-to-current phase angle and the real voltage-to-current phase angle shown in FIG. 19 is a relation satisfied at an arbitrary real frequency. Therefore, equation (77) can be considered a general equation for correction calculation.

In Table 4 shown below, parameters during execution of a fourth simulation are shown. In this simulation, as shown in Table 4, the number of sampling points is increased to thirteen.

TABLE 4
Parameters in Fourth Simulation

| | Number of | | Amplitude | Initial phase | Amplitude | Initial phase |
|---|---|---|---|---|---|---|
| Sampling | sampling | Real | of input | angle of input | of input | angle of input |
| frequency | points | frequency | voltage | voltage | current | current |
| 1000 Hz | 13 | 62.1 Hz | 1 V | 25 DEG | 0.8 A | 0 DEG |

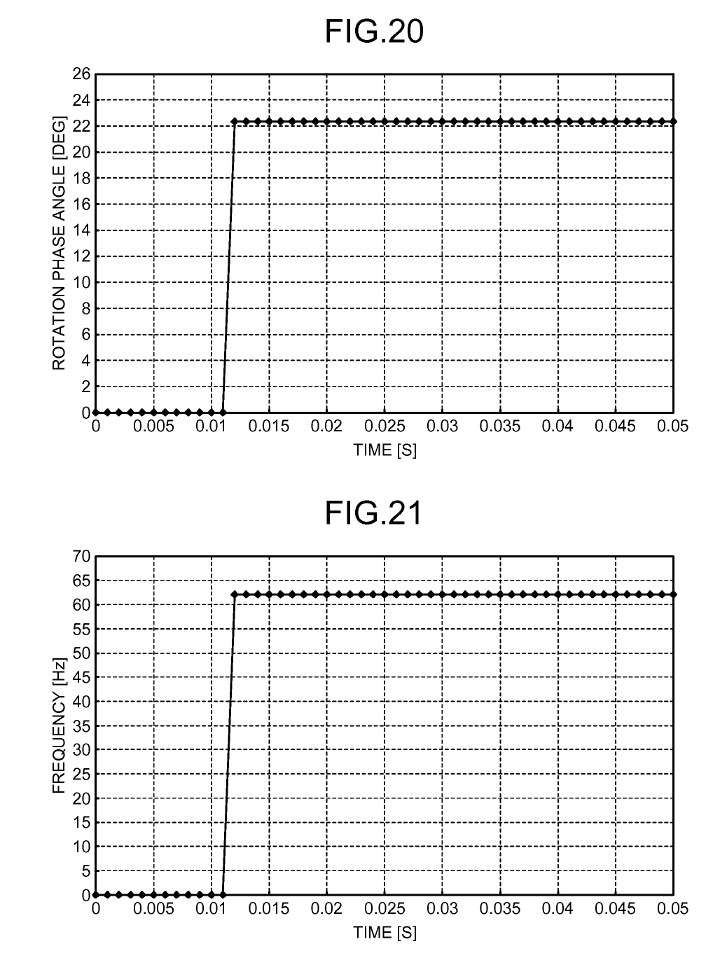

FIG. 20 is a graph of a rotation phase angle calculated in the fourth simulation. In this simulation, because the number of sampling points is thirteen, as shown in FIG. 20, a value of the rotation phase angle is calculated from a thirteenth point. The rotation phase angle is calculated as indicated by the following equation:

$$α = 2 {sin}^{- 1} ( \frac{{V}_{f 2}}{2 {V}_{f}} ) = 22.356 ( DEG ) \qquad ( 97 )$$

It is evident from comparison with the result of the first simulation that, when the sampling frequency increases, the normalized voltage amplitude decreases and the rotation phase angle decreases. This means that measurement accuracy of alternating-current electric quantities is at the same level as measurement accuracy of time. Therefore, the measurement accuracy (calculation accuracy) of the alternating-current electric quantities can be improved by increasing the number of sampling points. In the zero-cross method in the past, the measurement accuracy is improved by increasing the number of times of repetition of a converging operation for deciding a zero point. On the other hand, in this method, the measurement accuracy can be improved by increasing the number of sampling points. Therefore, it is possible to substantially improve the measurement accuracy of the alternating-current electric quantities.

FIG. 21 is a graph of a real frequency calculated in the fourth simulation. The real frequency is calculated as indicated by the following equation:

$$f = \frac{α}{2 π T} = \frac{22.356}{360} \times 1000 = 62.10 ( Hz ) \qquad ( 98 )$$

As indicated by equation (98), it is seen that a calculation result of the real frequency coincides with the parameters shown in Table 4.

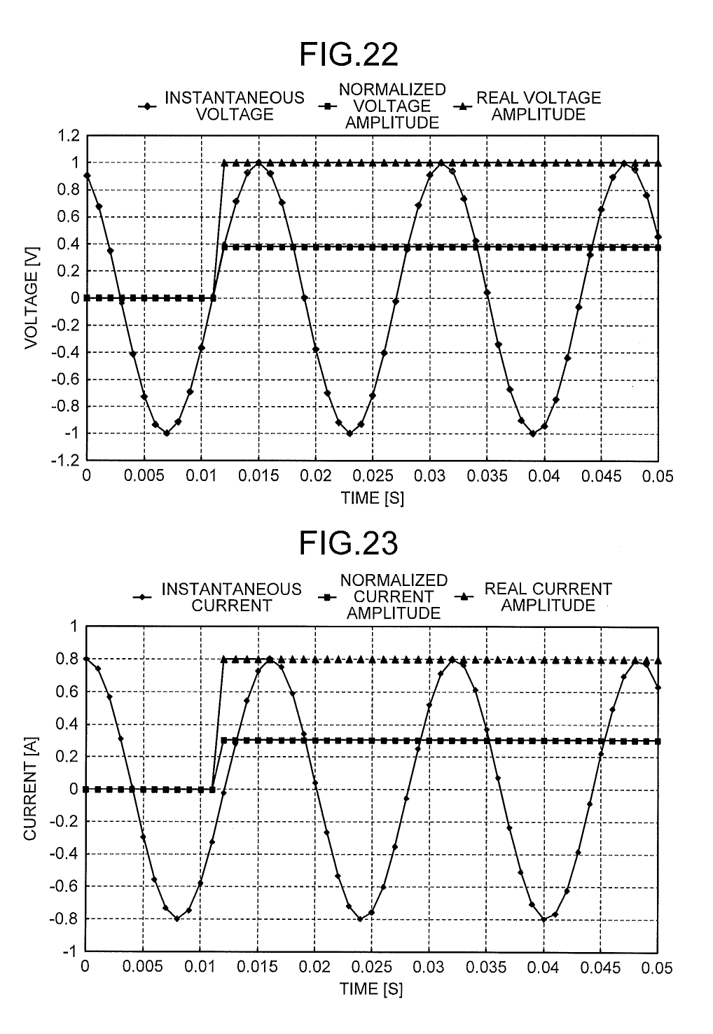

FIG. 22 is a graph of a normalized voltage amplitude and a real voltage amplitude calculated in the fourth simulation. In FIG. 22, a waveform connecting black diamond signs represents an instantaneous voltage waveform used in this simulation, a waveform connecting black square signs represents the normalized voltage amplitude, and a waveform connecting black triangle signs represents the real voltage amplitude.

The normalized voltage amplitude is calculated as indicated by the following equation:

$${V}_{f} = \sqrt{\frac{1}{10} ( {\sum }_{k = 3}^{12} ( {v}_{k}^{2} - {v}_{k - 1} {v}_{k + 1} ) )} = 0.38036 ( V ) \qquad ( 99 )$$

The real voltage amplitude is calculated as indicated by the following equation:

$$V = \frac{{V}_{f}}{sin α} = \frac{0.38036}{sin ( 22.356 )} = 1 ( V ) \qquad ( 100 )$$

As indicated by equation (100), it is seen that a calculation result of the real voltage amplitude coincides with the parameters shown in Table 4.

FIG. 23 is a graph of a normalized current amplitude and a real current amplitude calculated in the fourth simulation. In FIG. 23, a waveform connecting black diamond signs represents an instantaneous current waveform used in this simulation, a waveform connecting black square signs represents the normalized current amplitude, and a waveform connecting black triangle signs represents the real current amplitude.

The normalized current amplitude is calculated as indicated by the following equation:

$${I}_{f} = \sqrt{\frac{1}{10} ( {\sum }_{k = 2}^{12} ( {i}_{k}^{2} - {i}_{k - 1} {i}_{k + 1} ) )} = 0.304288 ( A ) \qquad ( 101 )$$

The real current amplitude is calculated as indicated by the following equation:

$$I = \frac{{I}_{f}}{sin α} = \frac{0.304288}{sin ( 22.356 )} = 0.8 ( A ) \qquad ( 102 )$$

As indicated by equation (102), it is seen that a calculation result of the real current amplitude coincides with the parameters shown in Table 4.

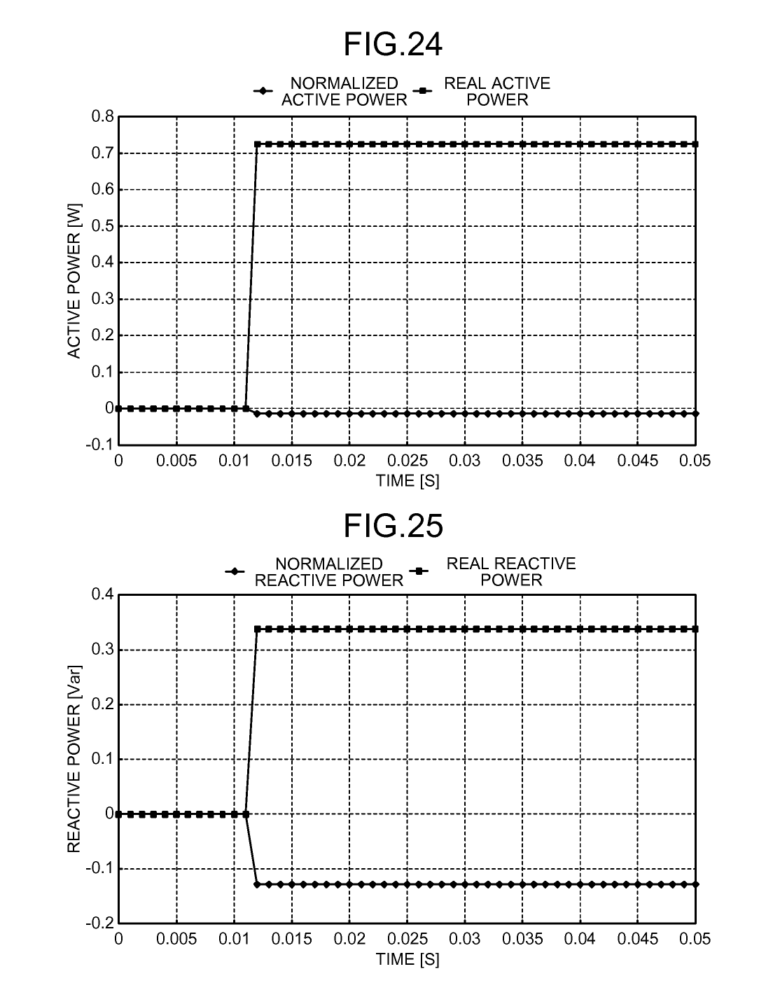

FIG. 24 is a graph of a normalized active power and a real active power calculated in the fourth simulation. In FIG. 24, a waveform connecting black diamond sings represents the normalized active power and a waveform connecting black square signs represents the real active power.

The normalized active power is calculated as indicated by the following equation:

$${P}_{f} = \frac{1}{10} ( {\sum }_{k = 3}^{12} ( {v}_{k} {i}_{k} - {v}_{k - 1} {i}_{k + 1} ) ) = - 0.01404 ( W ) \qquad ( 103 )$$

The real active power is calculated as indicated by the following equation:

P=VI cos φ=1×0.8×cos(25)=0.72505 (W) (104)

In this simulation, regardless of the fact that signs of the normalized active power and the real active power are different, a correct real active power is obtained by correction calculation.

FIG. 25 is a graph of a normalized reactive power and a real reactive power calculated in the fourth simulation. In FIG. 25, a waveform connecting black diamond signs represents the normalized reactive power and a waveform connecting black square signs represents the real reactive power.

The normalized reactive power is calculated as indicated by the following equation:

$${Q}_{f} = \frac{1}{10} ( {\sum }_{k = 3}^{12} ( {v}_{k + 1} {i}_{k} - {v}_{k} {i}_{k + 1} ) ) = - 0.1286 ( Var ) \qquad ( 105 )$$

The real reactive power is calculated as indicated by the following equation:

Q=VI sin φ=1×0.8×(25)=0.33810(Var) (106)

In this simulation, regardless of the fact that signs of the normalized reactive power and the real reactive power are different, a correct real reactive power is obtained by correction calculation.

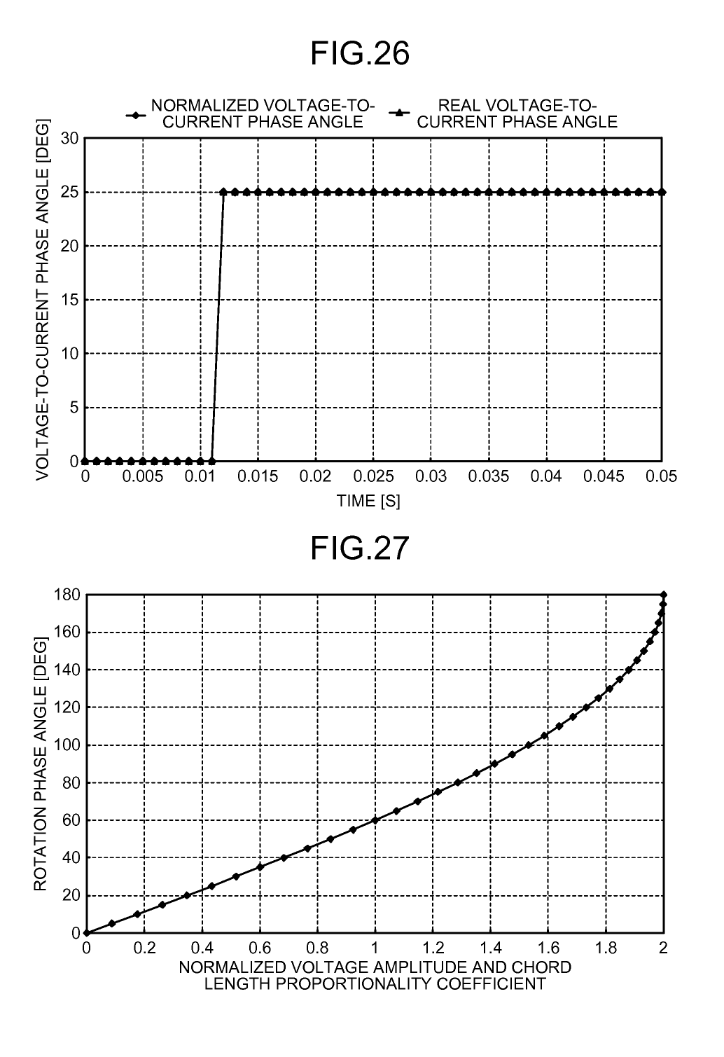

FIG. 26 is a graph of a normalized voltage-to-current phase angle and a real voltage-to-current phase angle calculated in the fourth simulation. In FIG. 26, a waveform connecting black diamond signs represents the normalized voltage-to-current phase angle and a waveform connecting black triangle signs represents the real voltage-to-current phase angle.

The normalized voltage-to-current phase angle is calculated as indicated by the following equation:

$${ϕ}_{f} = {cos}^{- 1} \frac{( - 0.01404 ) - ( - 0.1286 ) cos ( 22.356 )}{1 \times 0.8 \times {sin}^{2} ( 22.356 )} = 25 ( DEG ) \qquad ( 107 )$$

According to equation (103), because the sign of the normalized reactive power is minus, the real voltage-to-current phase angle is calculated as indicated by the following equation:

φ=φ_{f}=25(DEG) (108)

As indicated by equation (108), it is seen that a calculation result of the real voltage-to-current phase angle coincides with the parameters shown in Table 4.

In the above explanation, two times the inverse sine value of the value obtained by dividing the normalized voltage chord length by two times the normalized voltage amplitude is calculated as the rotation phase angle. However, some protection control apparatus having low performance does not include a calculation function for the inverse sign function. It is difficult to apply the methods explained above in such a protection control apparatus. Therefore, in a method explained below, a method for enabling application to an apparatus not including the calculation function for the inverse sine function is presented.

First, two proportionality coefficients are defined below.

### (a) Normalized Voltage Amplitude and Chord Length Proportionality Coefficient

The normalized voltage amplitude and chord length proportionality coefficient is defined as indicated by the following equation:

$${K}_{vf} = \frac{{V}_{f 2}}{{V}_{f}} \qquad ( 109 )$$

In equation (109), V_{f} represents a normalized voltage amplitude and V_{f2} represents a normalized voltage chord length. Specifically, the normalized voltage amplitude and chord length proportionality coefficient (hereinafter referred to as “first proportionality coefficient” for convenience of explanation) represents a ratio of the normalized voltage chord length V_{f2} to the normalized voltage amplitude V_{f} (a value obtained by dividing the normalized voltage chord length V_{f2} by the normalized voltage amplitude V_{f}). If the first proportionality coefficient is used, the rotation phase angle α can be represented as indicated by the following equation:

$$α = 2 {sin}^{- 1} ( \frac{{V}_{f 2}}{2 {V}_{f}} ) = 2 {sin}^{- 1} ( \frac{{K}_{vf}}{2} ) \qquad ( 110 )$$

### (b) Sampling Frequency Proportionality Coefficient

The sampling frequency proportionality coefficient is defined as indicated by the following equation:

$${K}_{f} = \frac{f}{{f}_{s}} \qquad ( 111 )$$

In equation (111), f represents a real frequency and fₛ represents a sampling frequency. Specifically, the sampling frequency proportionality coefficient (hereinafter referred to as “second proportionality coefficient” to simplify explanation) represents a ratio of the real frequency f to the sampling frequency fₛ (a value obtained by dividing the real frequency f by the sampling frequency fₛ). A relation indicated by the following equation occurs between the second proportionality coefficient and the first proportionality coefficient.

$${K}_{f} = \frac{α}{2 π} = \frac{2 {sin}^{- 1} ( \frac{{V}_{f 2}}{2 {V}_{f}} )}{2 π} = \frac{{sin}^{- 1} ( \frac{{K}_{vf}}{2} )}{π} \qquad ( 112 )$$

FIG. 27 a characteristic chart for explaining a relation between the first proportionality coefficient (the normalized voltage amplitude and chord length proportionality coefficient) and the rotation phase angle.

In FIG. 27, a variation range of the first proportionality coefficient is 0 to 2. When FIG. 27 is referred to, matters explained below are clarified.
(a) When the first proportionality coefficient is 0, the rotation phase angle is 0 degree.
(b) When the first proportionality coefficient is 1, the rotation phase angle is 60 degrees.
(c) When the first proportionality coefficient is √(2), the rotation phase angle is 90 degrees.
(d) When the first proportionality coefficient is √(3), the rotation phase angle is 120 degrees.
(e) When the first proportionality coefficient is 2, the rotation phase angle is 180 degrees.

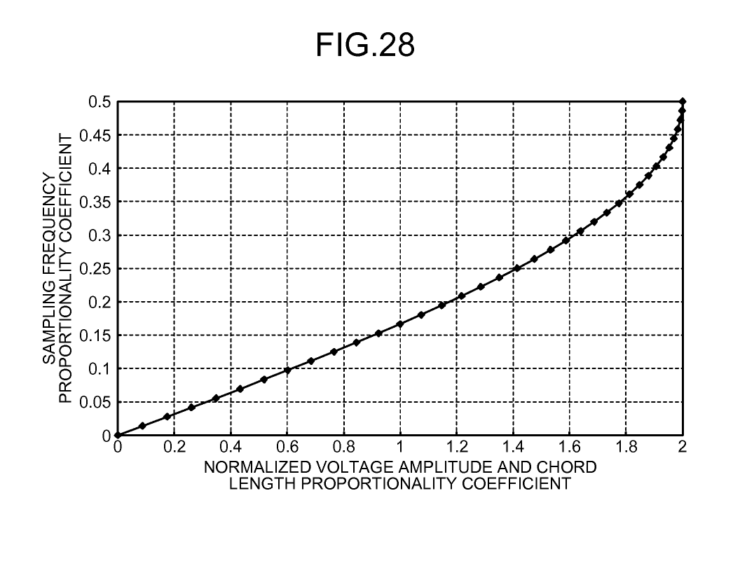

FIG. 28 is a characteristic chart for explaining a relation between the first proportionality coefficient (the normalized voltage amplitude and chord length proportionality coefficient) and the second proportionality coefficient (the sampling frequency proportionality coefficient). In FIG. 28, as in FIG. 27, a variation range of the first proportionality coefficient is 0 to 2. When FIG. 28 is refereed to, matters explained below are clarified.

(a) When the first proportionality coefficient is 0, the second proportionality coefficient is 0.
(b) When the first proportionality coefficient is 1, the second proportionality coefficient is ⅙.
(c) When the first proportionality coefficient is √(2), the second proportionality coefficient is ¼.
(d) When the first proportionality coefficient is √(3), the second proportionality coefficient is ⅓.
(e) When the first proportionality coefficient is 2, the second proportionality coefficient is ½.

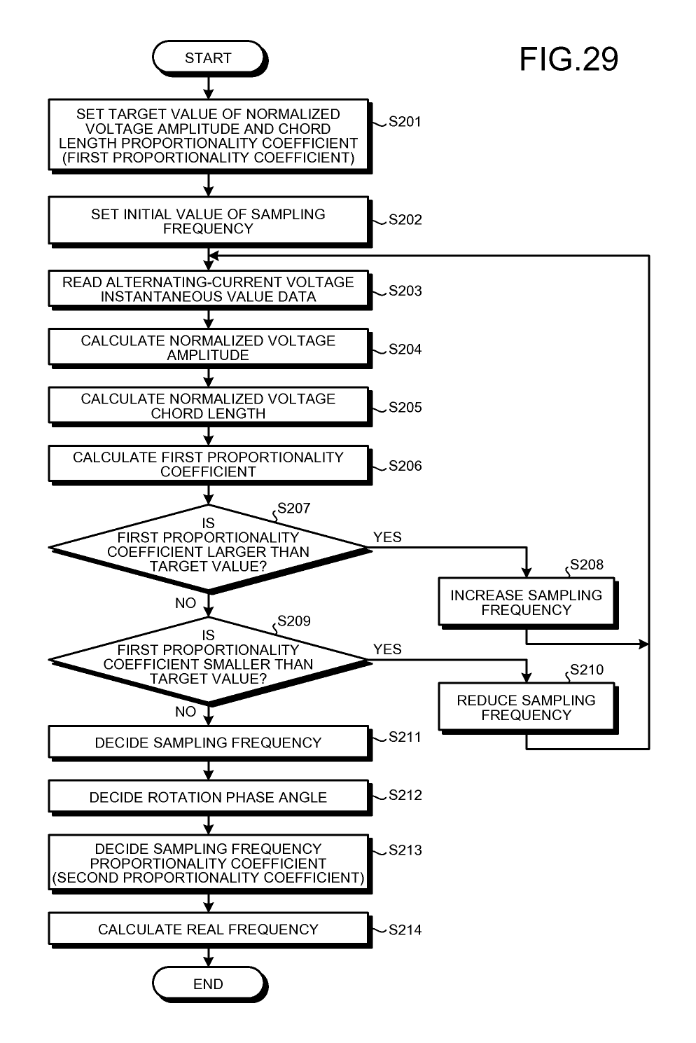

FIG. 29 is a flowchart for explaining a procedure for calculating a real frequency using a sampling frequency identifying method. In the flowchart of FIG. 9, the sampling frequency is fixed and the rotation phase angle is calculated using the time series data of instantaneous values sampled based on the fixed sampling frequency. However, in the flowchart of FIG. 29, the alternating-current electric quantity measuring apparatus 1 performs processing for calculating a value of a sampling frequency set as a desired target value (identification processing for a sampling frequency) and deciding a rotation phase angle from the calculated sampling frequency. The processing is explained using specific numerical values with reference to FIGS. 27 to 29. Parameters used in the explanation are as shown in Table 5 below.

TABLE 5
Parameters in Fifth Simulation

| | | Target value of | | |
|---|---|---|---|---|
| | | normalized | | |
| | | voltage | | Initial |
| | | amplitude and | | phase |
| Number of | | chord length | Amplitude | angle of |
| sampling | Real | proportionality | of input | input |
| points | frequency | coefficient | voltage | voltage |
| 4 | 15 Hz | 1 | 1 V | 0 DEG |

First, the alternating-current electric quantity measuring apparatus 1 sets a target value of the first proportionality coefficient (the normalized voltage amplitude and chord length proportionality coefficient) (step S201). For example, the alternating-current electric quantity measuring apparatus 1 sets a following target value of normalized voltage amplitude and chord length proportionality coefficient:

K_{Vf—}SET=1±0.001 (113)

Subsequently, the alternating-current electric quantity measuring apparatus 1 sets an initial value of the sampling frequency (step S202). For example, the alternating-current electric quantity measuring apparatus 1 sets the following sampling frequency:

f_{S0}=600(Hz) (114)

In this case, a time interval corresponding to the sampling frequency is as indicated by the following equation:

$$T = \frac{1}{{f}_{s 0}} = 0.0016667 ( S ) \qquad ( 115 )$$

Subsequently, the alternating-current electric quantity measuring apparatus 1 reads alternating-current voltage instantaneous value data (step S203). For example, the alternating-current electric quantity measuring apparatus 1 reads four voltage instantaneous value data (v₁, v₂, v₃, and v₄).

Subsequently, the alternating-current electric quantity measuring apparatus 1 calculates a normalized voltage amplitude (step S204). The alternating-current electric quantity measuring apparatus 1 calculates the normalized voltage amplitude as indicated by the following equation:

V_{f}=\sqrt{v²₃−v₂v₄}=0.15643 (V) (116)

Similarly, the alternating-current electric quantity measuring apparatus 1 calculates a normalized voltage chord length (step S205). The alternating-current electric quantity measuring apparatus 1 calculates the normalized voltage chord length as indicated by the following equation:

V_{f2}=\sqrt{(v₃−v₂)²−(v₂−v₁)(v₄−v₃)}=0.024547 (V) (117)

Subsequently, the alternating-current electric quantity measuring apparatus 1 calculates the first proportionality coefficient (the normalized voltage amplitude and chord length proportionality coefficient) (step S206). The alternating-current electric quantity measuring apparatus 1 calculates the first proportionality coefficient as indicated by the following equation:

$${K}_{vf} = \frac{{V}_{f 2}}{{V}_{f}} = 0.1569 \qquad ( 118 )$$

The alternating-current electric quantity measuring apparatus 1 discriminates based on the following discriminant whether the first proportionality coefficient calculated at step S206 is larger than a desired target value (e.g., “first target value”) (step S207).

K_{Vf}>(1+0.001)? (119)

When equation (119) holds (Yes at step S207), the alternating-current electric quantity measuring apparatus 1 performs processing for increasing the sampling frequency (step S208). The alternating-current electric quantity measuring apparatus 1 returns to step S203. As the processing for increasing the sampling frequency, processing indicated by the following equation only has to be performed:

fₛ₀=fₛ₀+Δf (120)

A time interval corresponding to the sampling frequency is as indicated by the following equation:

$$T = \frac{1}{{f}_{s 0} + Δ f} \qquad ( 121 )$$

On the other hand, when equation (119) does not hold (No at step S207), the alternating-current electric quantity measuring apparatus 1 further discriminates based on the following discriminant whether the first proportionality coefficient is smaller than a desired target value (a “second target value” smaller than the “first target value”) (step S209).

K_{Vf}<(1−0.001)? (122)

When equation (122) holds (Yes at step S209), the alternating-current electric quantity measuring apparatus 1 performs processing for reducing the sampling frequency this time (step S210). The alternating-current electric quantity measuring apparatus 1 returns to step S203. As the processing for reducing the sampling frequency, processing indicated by the following equation only has to be performed.

fₛ₀=fₛ₀−Δf (123)

A time interval corresponding to the sampling frequency is as indicated by the following equation:

$$T = \frac{1}{{f}_{s 0} + Δ f} \qquad ( 124 )$$

On the other hand, when equation (122) does not hold (No at step S209), the alternating-current electric quantity measuring apparatus 1 decides the sampling frequency (step S211). When the alternating-current electric quantity measuring apparatus 1 reaches step S211, a calculated value of the first proportionality coefficient is already present in a dead zone near the target value. Therefore, it is possible to decide the sampling frequency at this point. In this case, the following sampling frequency is decided:

fₛ=90 (Hz) (125)

Further, the alternating-current electric quantity measuring apparatus 1 decides a rotation phase angle (step S212). In the case of this example, if a point where the first proportionality coefficient is “1” is read in the characteristic chart of FIG. 27, the rotation phase angle is given by the following equation:

α=60 (DEG) (126)

Further, the alternating-current electric quantity measuring apparatus 1 decides the second proportionality coefficient (step S213). In the case of this example, if the point where the first proportionality coefficient is “1” is read in the characteristic chart of FIG. 28, the second proportionality coefficient is given by the following equation:

K_{f}=⅙=0.166667 (127)

Finally, the alternating-current electric quantity measuring apparatus 1 calculates a real frequency (step S214) and ends this flow. In the case of this example, the real frequency is calculated as indicated by the following equation:

f₁=Kf×fₛ=0.166667×89.9999=15.0 (Hz) (128)

In the processing explained with reference to the flowchart of FIG. 29, the alternating-current voltage instantaneous value data is used. However, a flow of the same processing can be realized by using alternating current instantaneous value data. In this case, the processing only has to be performed with a ratio of the normalized current chord length I_{f2} to the normalized current amplitude I_{f} set as the “first proportionality coefficient”.

As explained above, with the alternating-current electric quantity measuring apparatus according to this embodiment, a voltage amplitude calculated by the square integral operation of at least three voltage instantaneous values continuously sampled at a sampling frequency twice or more as high as a frequency of an alternating-current voltage to be measured is normalized and calculated as a normalized voltage amplitude. A voltage chord length calculated by the square integral operation of three voltage chord length instantaneous values representing an end-to-end distance between adjacent two voltage instantaneous values among at least four continuous voltage instantaneous values including the three voltage instantaneous values, which are sampled at the sampling frequency and used in calculating the normalized voltage amplitude, is normalized by an amplitude value of an alternating-current voltage and calculated as a normalized voltage chord length. A rotation phase angle in one period time of sampling is calculated using the normalized voltage amplitude and the normalized voltage chord length. True values concerning an alternating-current voltage amplitude, an alternating current amplitude, an active power, and a reactive power are calculated using the calculated rotation phase angle, normalized voltage amplitude, and normalized current amplitude. Therefore, even if the measuring target is operating at a frequency deviating from a system rated frequency, it is possible to perform highly-accurate measurement of alternating-current electric quantities.

With the alternating-current electric quantity measuring apparatus according to this embodiment, it is possible to calculate alternating-current electric quantities such as a real voltage amplitude and a real current amplitude using calculated rotation phase angle, normalized voltage amplitude, normalized current amplitude, and the like without using the least square method that requires a large calculation amount and a large calculation load. Further, it is possible to calculate alternating-current electric quantities such as a real active power and a real reactive power using calculated rotation phase angle, normalized voltage amplitude, normalized current amplitude, normalized active power, normalized reactive power, normalized voltage-to-current phase angle, and the like. Therefore, it is possible to perform high-speed and highly-accurate measurement of alternating-current electric quantities.

### INDUSTRIAL APPLICABILITY

As explained above, the alternating-current electric quantity measuring apparatus according to the present invention is useful as an invention that enables high-accurate measurement of alternating-current electric quantities even if a measurement target is operating at a frequency deviating from a system rated frequency.

### REFERENCE SIGNS LIST

1 ALTERNATING-CURRENT ELECTRIC QUANTITY MEASURING APPARATUS
2 ALTERNATING-CURRENT-VOLTAGE/CURRENT-INSTANTANEOUS-VALUE-VALUE-DATA INPUT UNIT
3 NORMALIZED-VOLTAGE-AMPLITUDE CALCULATING UNIT
4 NORMALIZED-VOLTAGE-CHORD-LENGTH CALCULATING UNIT
5 ROTATION-PHASE-ANGLE CALCULATING UNIT
6 FREQUENCY CALCULATING UNIT
7 REAL-VOLTAGE-AMPLITUDE CALCULATING UNIT
8 NORMALIZED-CURRENT-AMPLITUDE CALCULATING UNIT
9 REAL-CURRENT-AMPLITUDE CALCULATING UNIT
10 NORMALIZED-ACTIVE-POWER CALCULATING UNIT
11 NORMALIZED-REACTIVE-POWER CALCULATING UNIT
12 NORMALIZED-VOLTAGE-TO-CURRENT-PHASE-ANGLE CALCULATING UNIT
13 REAL-VOLTAGE-TO-CURRENT-PHASE-ANGLE CALCULATING UNIT
14 REAL-ACTIVE-POWER CALCULATING UNIT
15 REAL-REACTIVE-POWER CALCULATING UNIT
16 INTERFACE
17 STORING UNIT

1. An alternating-current electric quantity measuring apparatus comprising:
a normalized-voltage-amplitude calculating unit configured to calculate a normalized voltage amplitude by normalizing a voltage amplitude calculated by a square integral operation of at least three continuous voltage instantaneous values obtained by sampling an alternating-current voltage to be measured at a sampling frequency twice or higher than a frequency of the alternating-current voltage;
a normalized-voltage-chord-length calculating unit configured to calculate a normalized voltage chord length by normalizing a voltage chord length calculated by the square integral operation of three voltage chord length instantaneous values representing an end-to-end distance between two adjacent voltage instantaneous values in at least four continuous voltage instantaneous values including the three voltage instantaneous values, which are sampled at the sampling frequency and used in calculating the normalized voltage amplitude; and
a frequency calculating unit configured to calculate a rotation phase angle in one period time of sampling using the normalized voltage amplitude and the normalized voltage chord length and calculate a frequency of the alternating-current voltage using the calculated rotation phase angle.

2. An alternating-current electric quantity measuring apparatus comprising:
a normalized-current-amplitude calculating unit configured to calculate a normalized current amplitude by normalizing a current amplitude calculated by a square integral operation of at least three continuous current instantaneous values obtained by sampling an alternating current to be measured at a sampling frequency twice or higher than a frequency of the alternating current;
a normalized-current-chord-length calculating unit configured to calculate a normalized current chord length by normalizing a current chord length calculated by the square integral operation of three current chord length instantaneous values representing an end-to-end distance between two adjacent current instantaneous values in at least four continuous current instantaneous values including the three current instantaneous values, which are sampled at the sampling frequency and used in calculating the normalized current amplitude; and
a frequency calculating unit configured to calculate a rotation phase angle in one period time of sampling using the normalized current amplitude and the normalized current chord length and calculate a frequency of the alternating current using the calculated rotation phase angle.

3. An alternating-current electric quantity measuring apparatus comprising:
a normalized-voltage-amplitude calculating unit configured to calculate a normalized voltage amplitude by normalizing a voltage amplitude calculated by a square integral operation of at least three continuous voltage instantaneous values obtained by sampling an alternating-current voltage to be measured at a sampling frequency twice or higher than a frequency of the alternating-current voltage;
a normalized-voltage-chord-length calculating unit configured to calculate a normalized voltage chord length obtained by normalizing a voltage chord length calculated by the square integral operation of three voltage chord length instantaneous values representing an end-to-end distance between two adjacent voltage instantaneous values in at least four continuous voltage instantaneous values including the three voltage instantaneous values, which are sampled at the sampling frequency and used in calculating the normalized voltage amplitude;
a rotation-phase-angle calculating unit configured to calculate a rotation phase angle in one period time of sampling using the normalized voltage amplitude and the normalized voltage chord length; and
a real-voltage-amplitude calculating unit configured to calculate a real voltage amplitude, which is a true value of the alternating-current voltage amplitude, using the normalized voltage amplitude and the rotation phase angle.

4. An alternating-current electric quantity measuring apparatus comprising:
a normalized-current-amplitude calculating unit configured to calculate a normalized current amplitude by normalizing a current amplitude calculated by a square integral operation of at least three current instantaneous values obtained by sampling an alternating current to be measured at a sampling frequency twice or higher than a frequency of the alternating current;
a normalized-current-chord-length calculating unit configured to calculate a normalized current chord length obtained by normalizing a current chord length calculated by the square integral operation of three current chord length instantaneous values representing an end-to-end distance between two adjacent current instantaneous values in at least four continuous current instantaneous values including the three current instantaneous values, which are sampled at the sampling frequency and used in calculating the normalized current amplitude;
a rotation-phase-angle calculating unit configured to calculate a rotation phase angle in one period time of sampling using the normalized current amplitude and the normalized current chord length; and
a real-current-amplitude calculating unit configured to calculate a real current amplitude, which is a true value of the alternating current amplitude, using the normalized current amplitude and the rotation phase angle.

5. An alternating-current electric quantity measuring apparatus comprising:
a normalized-voltage-amplitude calculating unit configured to calculate a normalized voltage amplitude by normalizing a voltage amplitude calculated by a square integral operation of at least three continuous voltage instantaneous values obtained by sampling an alternating-current voltage to be measured at a sampling frequency twice or higher than a frequency of the alternating-current voltage;
a normalized-voltage-chord-length calculating unit configured to calculate a normalized voltage chord length by normalizing a voltage chord length calculated by the square integral operation of three voltage chord length instantaneous values representing an end-to-end distance between two adjacent voltage instantaneous values in at least four continuous voltage instantaneous values including the three voltage instantaneous values, which are sampled at the sampling frequency and used in calculating the normalized voltage amplitude;
a normalized-current-amplitude calculating unit configured to calculate a normalized current amplitude by normalizing a current amplitude calculated by the square integral operation of at least three continuous current instantaneous values obtained by sampling an alternating current to be measured at a sampling frequency twice or higher than a frequency of the alternating current;
a rotation-phase-angle calculating unit configured to calculate a rotation phase angle in one period time of sampling using the normalized voltage amplitude and the normalized voltage chord length;
a real-voltage-amplitude calculating unit configured to calculate a real voltage amplitude, which is a true value of the alternating-current voltage amplitude, using the normalized voltage amplitude and the rotation phase angle; and
a real-current-amplitude calculating unit configured to calculate a real current amplitude, which is a true value of the alternating current amplitude, using the normalized current amplitude and the rotation phase angle.

6. An alternating-current electric quantity measuring apparatus comprising:
a normalized-voltage-amplitude calculating unit configured to calculate a normalized voltage amplitude by normalizing a voltage amplitude calculated by a square integral operation of at least three continuous voltage instantaneous values obtained by sampling an alternating-current voltage to be measured at a sampling frequency twice or higher than a frequency of the alternating-current voltage;
a normalized-voltage-chord-length calculating unit configured to calculate a normalized voltage chord length by normalizing a voltage chord length calculated by the square integral operation of three voltage chord length instantaneous values representing an end-to-end distance between two adjacent voltage instantaneous values in at least four continuous voltage instantaneous values including the three voltage instantaneous values, which are sampled at the sampling frequency and used in calculating the normalized voltage amplitude;
a normalized-current-chord-length calculating unit configured to calculate a normalized current chord length by normalizing a current chord length calculated by the square integral operation of three current chord length instantaneous values representing an end-to-end distance between two adjacent current instantaneous values in at least four continuous current instantaneous values obtained by sampling an alternating current to be measured at a sampling frequency twice or higher than a frequency of the alternating current;
a rotation-phase-angle calculating unit configured to calculate a rotation phase angle in one period time of sampling using the normalized voltage amplitude and the normalized voltage chord length;
a real-voltage-amplitude calculating unit configured to calculate a real voltage amplitude, which is a true value of the alternating-current voltage amplitude, using the normalized voltage amplitude and the rotation phase angle; and
a real-current-amplitude calculating unit configured to calculate a real current amplitude, which is a true value of the alternating current amplitude, using the normalized current amplitude and the rotation phase angle.

7. The alternating-current electric quantity measuring apparatus according to claim 5, comprising:
a frequency calculating unit configured to calculate a frequency of the alternating-current voltage using the rotation phase angle;
a normalized-active-power calculating unit configured to calculate a normalized active power by normalizing an active power obtained by performing the square integral operation of a product of predetermined two voltage instantaneous values selected from the predetermined three continuous voltage instantaneous values sampled and predetermined two current instantaneous values selected from three current instantaneous values sampled at same time as the predetermined three voltage instantaneous values;
a normalized-reactive-power calculating unit configured to calculate a normalized reactive power by normalizing a reactive power obtained by performing the square integral operation of a product of predetermined two voltage instantaneous values selected from predetermined three voltage instantaneous values and predetermined two continuous current instantaneous values sampled at the sampling frequency and selected from the three current instantaneous values;
a normalized-voltage-to-current-phase-angle calculating unit configured to calculate a normalized voltage-to-current phase angle between the normalized active power and the normalized reactive power using the normalized active power, the normalized reactive power, and the rotation phase angle;
a real-voltage-to-current-phase-angle calculating unit configured to calculate a real voltage-to-current phase angle, which is a true value of a phase angle, between the alternating-current voltage and the alternating current using the frequency calculated by the frequency-calculating unit and the normalized voltage-to-current phase angle; and
a real-active-power calculating unit configured to calculate a real active power, which is a true value of an active power, using the real voltage amplitude, the real current amplitude, and the normalized voltage-to-current phase angle.

8. The alternating-current electric quantity measuring apparatus according to claim 5, comprising:
a frequency calculating unit configured to calculate a frequency of the alternating-current voltage using the rotation phase angle;
a normalized-active-power calculating unit configured to calculate a normalized active power by normalizing an active power obtained by performing the square integral operation of a product of predetermined two voltage instantaneous values selected from the predetermined three continuous voltage instantaneous values sampled and predetermined two continuous current instantaneous values selected from three current instantaneous values sampled at same time as the predetermined three voltage instantaneous values;
a normalized-reactive-power calculating unit configured to calculate a normalized reactive power by normalizing a reactive power obtained by performing the square integral operation of a product of predetermined two voltage instantaneous values selected from the predetermined three voltage instantaneous values and predetermined two continuous current instantaneous values sampled at the sampling frequency and selected from the three current instantaneous values;
a normalized-voltage-to-current-phase-angle calculating unit configured to calculate a normalized voltage-to-current phase angle between the normalized active power and the normalized reactive power using the normalized active power, the normalized reactive power, and the rotation phase angle;
a real-voltage-to-current-phase-angle calculating unit configured to calculate a real voltage-to-current phase angle, which is a true value of a phase angle, between the alternating-current voltage and the alternating current using the frequency calculated by the frequency-calculating unit and the normalized voltage-to-current phase angle; and
a real-reactive-power calculating unit configured to calculate a real reactive power, which is a true value of a reactive power, using the real voltage amplitude, the real current amplitude, and the normalized voltage-to-current phase angle.

9. The alternating-current electric quantity measuring apparatus according to claim 5, comprising:
a frequency calculating unit configured to calculate a frequency of the alternating-current voltage using the rotation phase angle;
a normalized-active-power calculating unit configured to calculate a normalized active power by normalizing an active power obtained by performing the square integral operation of a product of predetermined two voltage instantaneous values selected from the predetermined three continuous voltage instantaneous values sampled and predetermined two continuous current instantaneous values selected from three current instantaneous values sampled at same time as the voltage instantaneous values of the predetermined three points;
a normalized-reactive-power calculating unit configured to calculate a normalized reactive power by normalizing a reactive power obtained by performing the square integral operation of a product of predetermined two voltage instantaneous values selected from the predetermined three voltage instantaneous values and predetermined two continuous current instantaneous values sampled at the sampling frequency and selected from the three current instantaneous values;
a normalized-voltage-to-current-phase-angle calculating unit configured to calculate a normalized voltage-to-current phase angle between the normalized active power and the normalized reactive power using the normalized active power, the normalized reactive power, and the rotation phase angle;
a real-voltage-to-current-phase-angle calculating unit configured to calculate a real voltage-to-current phase angle, which is a true value of a phase angle, between the alternating-current voltage and the alternating current using the frequency calculated by the frequency-calculating unit and the normalized voltage-to-current phase angle;
a real-active-power calculating unit configured to calculate a real active power, which is a true value of an active power, using the real voltage amplitude, the real current amplitude, and the normalized voltage-to-current phase angle; and
a real-reactive-power calculating unit configured to calculate a real reactive power, which is a true value of a reactive power, using the real voltage amplitude, the real current amplitude, and the normalized voltage-to-current phase angle.

10-18. (canceled)

19. The alternating-current electric quantity measuring apparatus according to claim 6, comprising:
a frequency calculating unit configured to calculate a frequency of the alternating-current voltage using the rotation phase angle;
a normalized-active-power calculating unit configured to calculate a normalized active power by normalizing an active power obtained by performing the square integral operation of a product of predetermined two voltage instantaneous values selected from the predetermined three continuous voltage instantaneous values sampled and predetermined two current instantaneous values selected from three current instantaneous values sampled at same time as the predetermined three voltage instantaneous values;
a normalized-reactive-power calculating unit configured to calculate a normalized reactive power by normalizing a reactive power obtained by performing the square integral operation of a product of predetermined two voltage instantaneous values selected from predetermined three voltage instantaneous values and predetermined two continuous current instantaneous values sampled at the sampling frequency and selected from the three current instantaneous values;
a normalized-voltage-to-current-phase-angle calculating unit configured to calculate a normalized voltage-to-current phase angle between the normalized active power and the normalized reactive power using the normalized active power, the normalized reactive power, and the rotation phase angle;
a real-voltage-to-current-phase-angle calculating unit configured to calculate a real voltage-to-current phase angle, which is a true value of a phase angle, between the alternating-current voltage and the alternating current using the frequency calculated by the frequency-calculating unit and the normalized voltage-to-current phase angle; and
a real-active-power calculating unit configured to calculate a real active power, which is a true value of an active power, using the real voltage amplitude, the real current amplitude, and the normalized voltage-to-current phase angle.

20. The alternating-current electric quantity measuring apparatus according to claim 6, comprising:
a frequency calculating unit configured to calculate a frequency of the alternating-current voltage using the rotation phase angle;
a normalized-active-power calculating unit configured to calculate a normalized active power by normalizing an active power obtained by performing the square integral operation of a product of predetermined two voltage instantaneous values selected from the predetermined three continuous voltage instantaneous values sampled and predetermined two continuous current instantaneous values selected from three current instantaneous values sampled at same time as the predetermined three voltage instantaneous values;
a normalized-reactive-power calculating unit configured to calculate a normalized reactive power by normalizing a reactive power obtained by performing the square integral operation of a product of predetermined two voltage instantaneous values selected from the predetermined three voltage instantaneous values and predetermined two continuous current instantaneous values sampled at the sampling frequency and selected from the three current instantaneous values;
a normalized-voltage-to-current-phase-angle calculating unit configured to calculate a normalized voltage-to-current phase angle between the normalized active power and the normalized reactive power using the normalized active power, the normalized reactive power, and the rotation phase angle;
a real-voltage-to-current-phase-angle calculating unit configured to calculate a real voltage-to-current phase angle, which is a true value of a phase angle, between the alternating-current voltage and the alternating current using the frequency calculated by the frequency-calculating unit and the normalized voltage-to-current phase angle; and
a real-reactive-power calculating unit configured to calculate a real reactive power, which is a true value of a reactive power, using the real voltage amplitude, the real current amplitude, and the normalized voltage-to-current phase angle.

21. The alternating-current electric quantity measuring apparatus according to claim 6, comprising:
a frequency calculating unit configured to calculate a frequency of the alternating-current voltage using the rotation phase angle;
a normalized-active-power calculating unit configured to calculate a normalized active power by normalizing an active power obtained by performing the square integral operation of a product of predetermined two voltage instantaneous values selected from the predetermined three continuous voltage instantaneous values sampled and predetermined two continuous current instantaneous values selected from three current instantaneous values sampled at same time as the voltage instantaneous values of the predetermined three points;
a normalized-reactive-power calculating unit configured to calculate a normalized reactive power by normalizing a reactive power obtained by performing the square integral operation of a product of predetermined two voltage instantaneous values selected from the predetermined three voltage instantaneous values and predetermined two continuous current instantaneous values sampled at the sampling frequency and selected from the three current instantaneous values;
a normalized-voltage-to-current-phase-angle calculating unit configured to calculate a normalized voltage-to-current phase angle between the normalized active power and the normalized reactive power using the normalized active power, the normalized reactive power, and the rotation phase angle;
a real-voltage-to-current-phase-angle calculating unit configured to calculate a real voltage-to-current phase angle, which is a true value of a phase angle, between the alternating-current voltage and the alternating current using the frequency calculated by the frequency-calculating unit and the normalized voltage-to-current phase angle;
a real-active-power calculating unit configured to calculate a real active power, which is a true value of an active power, using the real voltage amplitude, the real current amplitude, and the normalized voltage-to-current phase angle; and
a real-reactive-power calculating unit configured to calculate a real reactive power, which is a true value of a reactive power, using the real voltage amplitude, the real current amplitude, and the normalized voltage-to-current phase angle.
